(19) United States
(12) Patent Application Publication
(10) Pub. No.: US 2026/0353691 A1
(43) Pub. Date: Nov. 5, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chun-Fu LU, Hsinchu (TW); Lung-Kun CHU, Hsinchu (TW); Shen-Yang LEE, Hsinchu (TW); Hsiang-Pi CHANG, Hsinchu (TW); Wang-Chun HUANG, Hsinchu (TW); Huang-Lin CHAO, Hsinchu (TW); Kuo-Cheng CHIANG, Hsinchu (TW); Chih-Hao WANG, Hsinchu (TW)

(73) Assignee: Taiwan Semiconductor Manufacturing Company, Ltd., Hsinchu (TW)

(21) Appl. No.: 19/744,054

(22) Filed: Jul. 16, 2026

Related U.S. Application Data
(63) Continuation of application No. 18/979,072, filed on Dec. 12, 2024.
(60) Provisional application No. 63/673,881, filed on Jul. 22, 2024.

(51) Int. Cl. H10D 30/01; H10D 30/00; H10D 30/43; H10D 30/67; H10D 62/10; H10D 62/83; H10D 62/832; H10D 64/01; H10D 84/01; H10D 84/83; H10P 14/60

(52) U.S. Cl. CPC H10D 30/0196; H10D 30/014; H10D 30/0191; H10D 30/43; H10D 30/502; H10D 30/508; H10D 30/509; H10D 30/6735; H10D 30/6739; H10D 30/6757; H10D 62/121; H10D 62/83; H10D 62/832; H10D 64/017; H10D 84/014; H10D 84/0142; H10D 84/0144; H10D 84/83135; H10D 84/83138; H10D 84/832; H10P 14/6339

(57) ABSTRACT

A method of manufacturing a semiconductor device includes forming an interfacial layer over a channel region and forming a metal-containing layer over the interfacial layer. A metal silicate layer is formed over the channel region after forming the metal-containing layer. A portion of the metal silicate layer is removed. A gate dielectric layer is formed over the channel region after removing the portion of the metal silicate layer, and a gate electrode layer is formed over the gate dielectric layer.

### RELATED APPLICATIONS

This application is a continuation application of U.S. patent application Ser. No. 18/979,072 filed Dec. 12, 2024, which claims priority to U.S. Provisional Application No. 63/673,881 filed Jul. 22, 2024, the entire disclosure of each of which is incorporated herein by reference.

### BACKGROUND

As the semiconductor industry has progressed into nanometer technology process nodes in pursuit of higher device density, higher performance, and lower costs, challenges from both fabrication and design issues have resulted in the development of field effect transistors (FETs) having three-dimensional designs, such as a multi-gate field effect transistor (FET) including a fin FET (FinFET) and a gate-all-around (GAA) FET. In a FinFET, a gate electrode is adjacent to three side surfaces of a channel region with a gate dielectric layer interposed therebetween. Because the gate structure surrounds (wraps) the fin on three surfaces, the transistor essentially has three gates controlling the current through the fin or channel region. In a GAA FET, all side surfaces of the channel region are surrounded by the gate electrode, which allows for fuller depletion in the channel region and result in less short-channel effects due to steeper sub-threshold current swing (SS) and smaller drain induced barrier lowering (DIBL). As transistor dimensions are continually scaled down to sub 20-25 nm technology nodes, further improvements of the GAA FET are required.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 shows a cross sectional view of one of the various stages of manufacturing a GAA FET semiconductor device according to an embodiment of the present disclosure.

FIG. 2A shows a cross sectional view and FIG. 2B shows an isometric view of one of the various stages of manufacturing a GAA FET semiconductor device according to embodiments of the present disclosure.

FIG. 3A shows a cross sectional view and FIG. 3B shows an isometric view of one of the various stages of manufacturing a GAA FET semiconductor device according to embodiments of the present disclosure.

FIG. 4 shows a cross sectional view of one of the various stages of manufacturing a GAA FET semiconductor device according to an embodiment of the present disclosure.

FIG. 5 shows a cross sectional view of one of the various stages of manufacturing a GAA FET semiconductor device according to an embodiment of the present disclosure.

FIG. 6 shows a cross sectional view of one of the various stages of manufacturing a GAA FET semiconductor device according to an embodiment of the present disclosure.

FIG. 7 shows a cross sectional view of one of the various stages of manufacturing a GAA FET semiconductor device according to an embodiment of the present disclosure.

FIG. 8 shows a cross sectional view of one of the various stages of manufacturing a GAA FET semiconductor device according to an embodiment of the present disclosure.

FIG. 9A shows a cross sectional view of one of the various stages of manufacturing a GAA FET semiconductor device according to an embodiment of the present disclosure. FIG. 9B shows a cross sectional view of one of the various stages of manufacturing a GAA FET semiconductor device according to an embodiment of the present disclosure.

FIGS. 10A and 10B show a cross sectional view and an isometric view of one of the various stages of manufacturing a GAA FET semiconductor device according to an embodiment of the present disclosure.

FIG. 11 shows a cross sectional view of one of the various stages of manufacturing a GAA FET semiconductor device according to an embodiment of the present disclosure.

FIG. 12 shows a cross sectional view of one of the various stages of manufacturing a GAA FET semiconductor device according to an embodiment of the present disclosure.

FIG. 13 shows a cross sectional view of one of the various stages of manufacturing a GAA FET semiconductor device according to an embodiment of the present disclosure.

FIGS. 14A, 14B, 14C, and 14D show detailed cross sectional views of the various stages of manufacturing a semiconductor device according to an embodiment of the present disclosure.

FIG. 15A shows an atomic layer deposition operation according to embodiments of the present disclosure. FIG. 15B shows an atomic layer deposition gas supply profile according to embodiments of the present disclosure.

FIG. 16 shows a schematic view of a rapid thermal annealing operation according to embodiments of the present disclosure.

FIG. 17 shows a cross sectional view of one of the various stages of manufacturing a GAA FET semiconductor device according to an embodiment of the present disclosure.

FIG. 18 shows a cross sectional view of one of the various stages of manufacturing a GAA FET semiconductor device according to an embodiment of the present disclosure.

FIG. 19 shows a cross sectional view of one of the various stages of manufacturing a GAA FET semiconductor device according to an embodiment of the present disclosure.

FIG. 20 shows a cross sectional view of one of the various stages of manufacturing a GAA FET semiconductor device according to an embodiment of the present disclosure.

FIG. 21 shows a cross sectional view of one of the various stages of manufacturing a GAA FET semiconductor device according to an embodiment of the present disclosure.

FIG. 22 shows a cross sectional view of one of the various stages of manufacturing a GAA FET semiconductor device according to an embodiment of the present disclosure.

FIG. 23 shows a cross sectional view of one of the various stages of manufacturing a GAA FET semiconductor device according to an embodiment of the present disclosure.

FIG. 24 shows a cross sectional view of one of the various stages of manufacturing a GAA FET semiconductor device according to an embodiment of the present disclosure.

FIG. 25 shows a cross sectional view of one of the various stages of manufacturing a GAA FET semiconductor device according to an embodiment of the present disclosure.

FIG. 26 shows a cross sectional view of one of the various stages of manufacturing a GAA FET semiconductor device according to an embodiment of the present disclosure.

FIG. 27 shows a cross sectional view of one of the various stages of manufacturing a GAA FET semiconductor device according to an embodiment of the present disclosure.

FIG. 28 shows a cross sectional view of one of the various stages of manufacturing a GAA FET semiconductor device according to an embodiment of the present disclosure.

FIG. 29 shows a cross sectional view of one of the various stages of manufacturing a GAA FET semiconductor device according to an embodiment of the present disclosure.

FIG. 30 shows a cross sectional view of one of the various stages of manufacturing a GAA FET semiconductor device according to an embodiment of the present disclosure.

FIG. 31 shows a cross sectional view of one of the various stages of manufacturing a GAA FET semiconductor device according to an embodiment of the present disclosure.

FIG. 32 shows a cross sectional view of one of the various stages of manufacturing a GAA FET semiconductor device according to an embodiment of the present disclosure.

FIG. 33 shows a cross sectional view of one of the various stages of manufacturing a GAA FET semiconductor device according to an embodiment of the present disclosure.

FIG. 34 shows a cross sectional view of one of the various stages of manufacturing a GAA FET semiconductor device according to an embodiment of the present disclosure.

FIG. 35 illustrates detailed cross sectional views of the gate dielectric layer/metal-containing layer/semiconductor layer interface according to various embodiments of the present disclosure.

FIG. 36 shows a cross sectional view of a GAA FET semiconductor device according to an embodiment of the present disclosure.

FIG. 37, shows a cross sectional view of a GAA FET semiconductor device according to an embodiment of the present disclosure.

FIG. 38 shows a flow chart for a method of manufacturing a semiconductor device according to embodiments of the present disclosure.

FIG. 39 shows a flow chart for a method of manufacturing a semiconductor device according to embodiments of the present disclosure.

FIG. 40 shows a flow chart for a method of manufacturing a semiconductor device according to embodiments of the present disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C” (A, B, C, A and B, A and C, B and C, or A, B and C), and does not mean one element from A, one element from B and one element from C, unless otherwise described. In the entire disclosure, a source and a drain are interchangeably used, and a source/drain refers to one of or both of the source and the drain. Source/drain structure(s) may refer to a source or a drain, individually or collectively dependent upon the context. In the following embodiments, materials, configurations, dimensions, processes and/or operations as described with respect to one embodiment (e.g., one or more figures) may be employed in the other embodiments, and detailed description thereof may be omitted.

Disclosed embodiments relate to a semiconductor device, including a gate structure of a gate-all-around field effect transistor (GAA FET) and a stacked channel FET and their manufacturing methods. However, the disclosed methods and devices are also applicable to planar FETs and other semiconductor devices.

In embodiments of the disclosure, the thickness of interfacial layers between the gate dielectric layer and the channel regions of a FET are reduced, thereby reducing the capacitance equivalent thickness without increasing current leakage, thereby improving performance of the FET device can be improved.

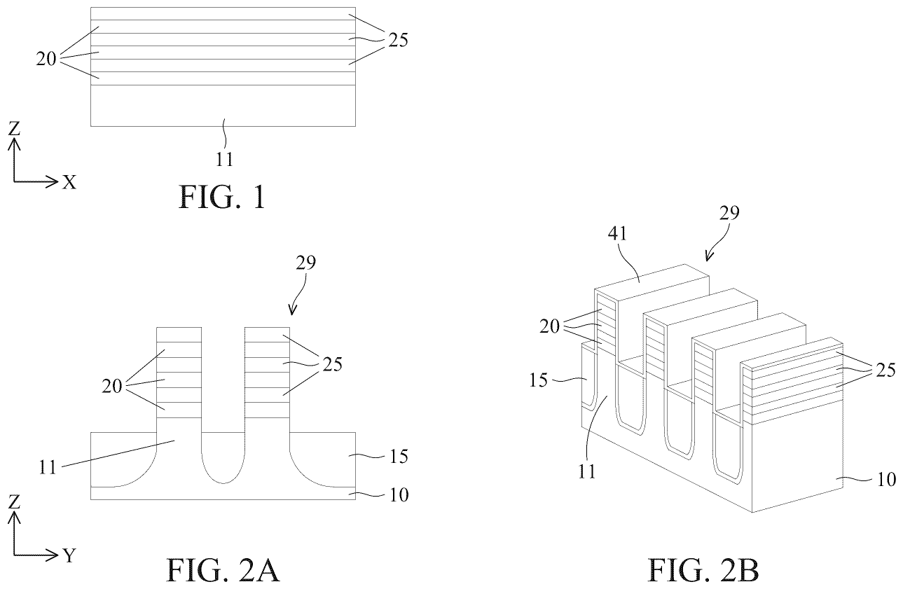

FIGS. 1 to 13 are schematic illustrations showing various stages of manufacturing a semiconductor FET device according to an embodiment of the present disclosure. It is understood that additional operations can be provided before, during, and after processes shown by FIGS. 1-13, and some of the operations described below can be replaced or eliminated, for additional embodiments of the method. The order of the operations/processes may be interchangeable.

As shown in FIG. 1, first semiconductor layers 20 and second semiconductor layers 25 are alternately formed over a substrate 10. The first semiconductor layers 20 and the second semiconductor layers 25 are made of materials having different lattice constants, and may include one or more layers of Si, Ge, SiGe, GaAs, InSb, GaP, GaSb, InAlAs, InGaAs, GaSbP, GaAsSb or InP.

In some embodiments, the first semiconductor layers 20 and the second semiconductor layers 25 are made of Si, a Si compound, SiGe, Ge or a Ge compound. In some embodiments, the first semiconductor layers 20 are made of Si. In some embodiments, the first semiconductor layers 20 are made of Si₁₋ₓGeₓ, where x is equal to or more than about 0.1 and equal to or less than about 0.6, and the second semiconductor layers 25 are Si or Si_{1-y}Ge_{y}, where y is smaller than x and equal to or less than about 0.2. In this disclosure, an “M compound” or an “M based compound” means the majority of the compound is M.

In other embodiments, the second semiconductor layers 25 are made of Si₁₋ₓGeₓ, where x is equal to or more than about 0.1 and equal to or less than about 0.6, and the first semiconductor layers 20 are made of Si or Si_{1-y}Ge_{y}, where y is smaller than x and equal to or less than about 0.2.

In some embodiments, the second semiconductor layer 25 is made of the same material as the semiconductor substrate 10.

The thickness of the semiconductor layers 25 in the Z-direction is in a range from about 5 nm to about 60 nm and the width of the semiconductor layers 25 along the Y-direction is in a range from about 5 nm to about 80 nm in some embodiments. In some embodiments, the width of the semiconductor layers is greater than the thickness. In certain embodiments, the width is up to twice or five times the thickness of the semiconductor nanostructures 25.

In some embodiments, the substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. The substrate 10 may include various regions that have been suitably doped with impurities (e.g., p-type or n-type conductivity). The dopants are, for example, boron difluoride (BF₂) for an n-type FinFET and phosphorus for a p-type FinFET in some embodiments. In certain embodiments, the substrate 10 is made of crystalline Si.

The substrate 10 may include in its surface region, one or more buffer layers (not shown). The buffer layers can serve to gradually change the lattice constant from that of the substrate to that of the source/drain structures. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In a particular embodiment, the substrate 10 includes silicon germanium (SiGe) buffer layers epitaxially grown on the silicon substrate 10. The germanium concentration of the SiGe buffer layers may increase from 30 atomic % germanium for the bottom-most buffer layer to 70 atomic % germanium for the top-most buffer layer.

The first semiconductor layer 20 and the second semiconductor layer 25 may be formed by one or more epitaxy or epitaxial (epi) processes. The epitaxy processes include chemical vapor deposition (CVD) deposition techniques (e.g., vapor-phase epitaxy (VPE) and/or ultra-high vacuum CVD (UHV-CVD)), molecular beam epitaxy, and/or other suitable processes.

The first semiconductor layers 20 and the second semiconductor layers 25 are epitaxially formed over the substrate 10 alternately. The thickness of the first semiconductor layers 20 may be equal to or greater than that of the second semiconductor layers 25, and is in a range from about 4 nm to about 30 nm in some embodiments, and is in a range from about 5 nm to about 15 nm in other embodiments. The thickness of the second semiconductor layers 25 is in a range from about 4 nm to about 30 nm in some embodiments, and is in a range from about 5 nm to about 15 nm in other embodiments. The thickness of the first semiconductor layers 20 may be the same as, or different from the thickness of the second semiconductor layers 25. Although three first semiconductor layers 20 and three second semiconductor layers 25 are shown in FIG. 1, the numbers are not limited to three, and can be one, two, or more than three, and less than twenty. In some embodiments, the number of the first semiconductor layers 20 is greater by one than the number of the second semiconductor layers 25 (i.e.—the top and bottom layers are the first semiconductor layer).

After the stacked semiconductor layers are formed, fin structures 29 are formed by using one or more lithography and etching operations, as shown in FIGS. 2A and 2B. The fin structures may be patterned by any suitable method. For example, the fin structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

As shown in FIG. 2A, the fin structures 29 extend in the X direction and are arranged in the Y direction. The number of the fin structures is not limited to two as shown in FIG. 2A, and may be as small as one and three or more (as shown in FIG. 2B). In some embodiments, one or more dummy fin structures are formed on both sides of the fin structures 29 to improve pattern fidelity in the patterning operations. As shown in FIG. 2A, the fin structures 29 have upper portions constituted by the stacked semiconductor layers 20, 25 and well portions 11 (a mesa structure).

The width of the upper portion of the fin structure 29 along the Y direction is in a range from about 5 nm to about 80 nm in some embodiments, and is in a range from about 10 nm to about 40 nm in other embodiments.

After the fin structures 29 are formed, an insulating material layer including one or more layers of insulating material is formed over the substrate so that the fin structures are fully embedded in the insulating layer. The insulating material for the insulating layer may include silicon oxide, silicon nitride, silicon oxynitride (SiON), SiOCN, SiCN, fluorine-doped silicate glass (FSG), or a low-k dielectric material, formed by LPCVD (low pressure chemical vapor deposition), plasma-enhanced CVD (PECVD) or flowable CVD. An anneal operation may be performed after the formation of the insulating layer. Then, a planarization operation, such as a chemical mechanical polishing (CMP) method and/or an etch-back method, is performed such that the upper surface of the uppermost second semiconductor layer 25 is exposed from the insulating material layer. In some embodiments, one or more fin liner layers are formed over the fin structures before forming the insulating material layer. In some embodiments, the fin liner layers include a first fin liner layer formed over the substrate 10 and sidewalls of the bottom part of the fin structures 11, and a second fin liner layer formed on the first fin liner layer. The fin liner layers are made of silicon nitride or a silicon nitride-based material (e.g., SiON, SiCN or SiOCN), in some embodiments. The fin liner layers may be deposited through one or more processes such as physical vapor deposition (PVD), chemical vapor deposition (CVD), or atomic layer deposition (ALD), although any acceptable process may be utilized.

Then, as shown in FIG. 2A, the insulating material layer is recessed to form an isolation insulating layer 15 so that the upper portions of the fin structures 29 are exposed. With this operation, the fin structures 29 are separated from each other by the isolation insulating layer 15, which is also called a shallow trench isolation (STI). The isolation insulating layer 15 may be made of suitable dielectric materials, such as silicon oxide, silicon nitride, silicon oxynitride, fluorine-doped silicate glass (FSG); low-k dielectrics, such as carbon doped oxides; extreme low-k dielectrics, such as porous carbon doped silicon dioxide; a polymer, such as polyimide; combinations of these, or the like. In some embodiments, the isolation insulating layer 15 is formed through a process such as CVD, flowable CVD (FCVD), or a spin-on-glass process, although any acceptable process may be used.

In some embodiments, the insulating material layer 15 is recessed until the upper portion of the fin structure (well layer) 11 is exposed. In other embodiments, the upper portion of the fin structure 11 is not exposed. The first semiconductor layers 20 are sacrificial layers which are subsequently partially removed, and the second semiconductor layers 25 are subsequently formed into semiconductor wires or sheets as channel layers of a GAA FET. In other embodiments, the second semiconductor layers 25 are sacrificial layers which are subsequently partially removed, and the first semiconductor layers 20 are subsequently formed into semiconductor wires or sheets as channel layers.

FIG. 2B is an isometric view showing a plurality of fin structures 29 separated by shallow trench isolations 15 after a sacrificial gate dielectric layer 41 is formed over the fin structures 29 and over the shallow trench isolation 15.

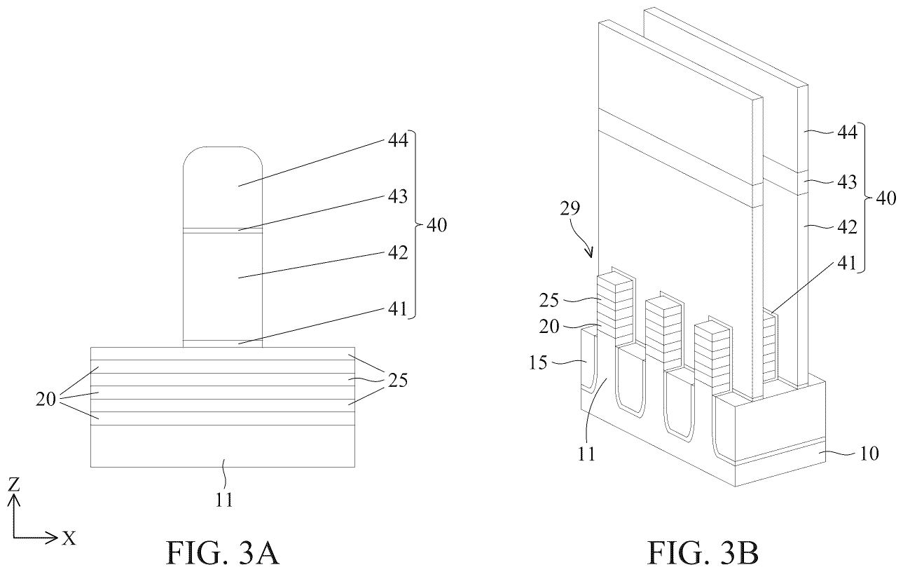

After the isolation insulating layer 15 is formed, one or more sacrificial (dummy) gate structures 40 are formed. FIGS. 3A and 3B illustrate a structure after one or more sacrificial gate structures 40 are formed over the exposed fin structures 29. FIG. 3B is an isometric view of the structure. The sacrificial gate structures 40 are formed over a portion of the fin structures 29 which is to be a channel region. The sacrificial gate structures 40 define the channel regions of the GAA FET. The sacrificial gate structures 40 include a sacrificial gate dielectric layer 41 and a sacrificial gate electrode layer 42. The sacrificial gate dielectric layer 41 includes one or more layers of insulating material, such as a silicon oxide-based material. In one embodiment, silicon oxide formed by CVD is used. The thickness of the sacrificial gate dielectric layer 41 is in a range from about 1 nm to about 5 nm in some embodiments.

The sacrificial gate structures 40 are formed by first blanket depositing the sacrificial gate dielectric layer 41 over the fin structures 29. A sacrificial gate electrode layer 42 is then blanket deposited on the sacrificial gate dielectric layer and over the fin structures, such that the fin structures are fully embedded in the sacrificial gate electrode layer. In some embodiments, the sacrificial gate electrode layer 42 includes silicon such as polycrystalline silicon or amorphous silicon. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. Subsequently, a mask layer is formed over the sacrificial gate electrode layer. In some embodiments, the mask layer includes a pad silicon nitride layer 43 and a silicon oxide mask layer 44.

Next, a patterning operation is performed on the mask layer and sacrificial gate electrode layer is patterned into the sacrificial gate structure 40, as shown in FIGS. 3A and 3B. In an embodiment, the sacrificial gate structure includes the sacrificial gate dielectric layer 41, the sacrificial gate electrode layer 42 (e.g., polysilicon), the pad silicon nitride layer 43 and the silicon oxide mask layer 44. By patterning the sacrificial gate structure, the stacked layers of the first and second semiconductor layers are partially exposed on opposite sides of the sacrificial gate structure, thereby defining source/drain regions, as shown in FIGS. 3A and 3B. In some embodiments, one sacrificial gate structure is formed over one or more fin structures, but the number of the sacrificial gate structures per fin structure is not limited to one. Two or more sacrificial gate structures are arranged in the X direction in some embodiments. In certain embodiments, one or more dummy sacrificial gate structures are formed on both sides of the sacrificial gate structures to improve pattern fidelity.

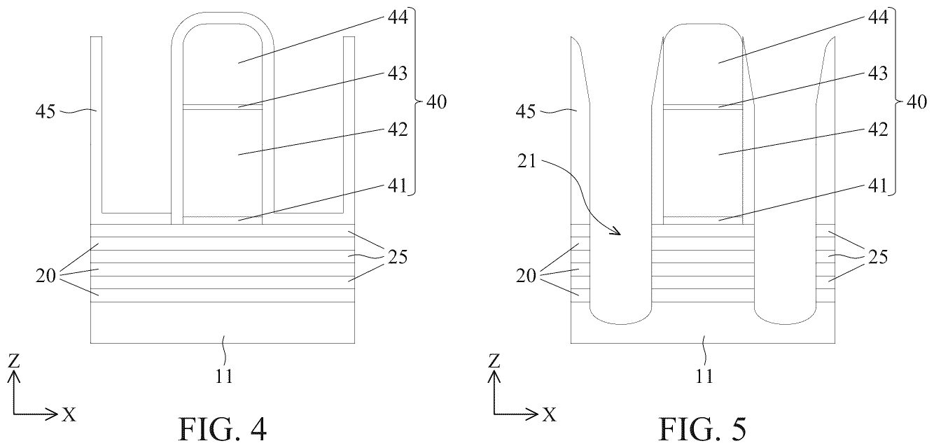

After the sacrificial gate structure 40 is formed, a first cover layer 45 for gate sidewall spacers is formed over the sacrificial gate structure 40, as shown in FIG. 4. The first cover layer 45 is deposited in a conformal manner so that it is formed to have substantially equal thicknesses on vertical surfaces, such as the sidewalls, horizontal surfaces, and the top of the sacrificial gate structure, respectively. In some embodiments, the first cover layer 45 has a thickness in a range from about 5 nm to about 20 nm. The first cover layer 45 includes one or more of silicon nitride, silicon oxide, SiON, SiCN, SiCO, SiOCN or any other suitable dielectric material. The cover layer 45 can be formed by ALD or CVD, or any other suitable method. In some embodiments, one or more additional cover layers are formed over the first cover layer to form multi-layer gate sidewall spacers.

Next, as shown in FIG. 5, the first cover layer 45 is anisotropically etched to remove the first cover layer 45 disposed on the source/drain region, while leaving the first cover layer 45 as sidewall spacers on side faces of the sacrificial gate structure 40. FIG. 5 shows a cross sectional view along the X direction. Then the stacked structure of the first semiconductor layers 20 and the second semiconductor layer 25 is etched down at the source/drain region, by using one or more lithography and etching operations, thereby forming a source/drain space 21. In some embodiments, the substrate 10 (or the bottom part of the fin structures 11) is also partially etched to form a mesa structure. In some embodiments, an n-type FET and a p-type FET are manufactured separately, and in such a case, a region for one type of FET is processed, and a region for the other type of FET is covered by a protective layer, such as a silicon nitride layer. In some embodiments, as shown in FIG. 5, the recessed fin structure has a U-shape. In other embodiments, the recessed fin structure has a V-shape showing (111) facets of silicon crystal. In other embodiments, the recess has a reverse trapezoid shape, or a rectangular shape.

In some embodiments, the recess is formed by a dry etching process, which may be anisotropic. The anisotropic etching process may be performed using a process gas mixture including BF₂, Cl₂, CH₃F, CH₄, HBr, O₂, Ar, and other etchant gases. Process gases may be activated into a plasma by any suitable method of generating the plasma, such as transformer coupled plasma (TCP) systems, inductively coupled plasma (ICP) systems, magnetically enhanced reactive ion techniques. The plasma is a remote plasma that is generated in a separate plasma generation chamber connected to the processing chamber in some embodiments. The process gases used in the plasma etching process includes etchant gases such as H₂, Ar, other gases, or a combination of gases. In some embodiments, carrier gases, such as N₂, Ar, He, Xe, are combined with a plasma etching process gas using hydrogen (H) radicals. The H radicals may be formed by flowing H₂ gas into a plasma generation chamber and igniting a plasma within the plasma generation chamber. In some embodiments, an additional gas may be ignited into a plasma within the plasma generation chamber, such as Ar. The H radicals may selectively etch (100) planes over (111) planes or (110) planes. In some cases, the etch rate of the (100) planes is about three times greater than the etch rate of (111) planes. Due to this selectivity, the etching by the H radicals may tend to slow or stop along (111) planes or (110) planes of silicon during the second patterning process.

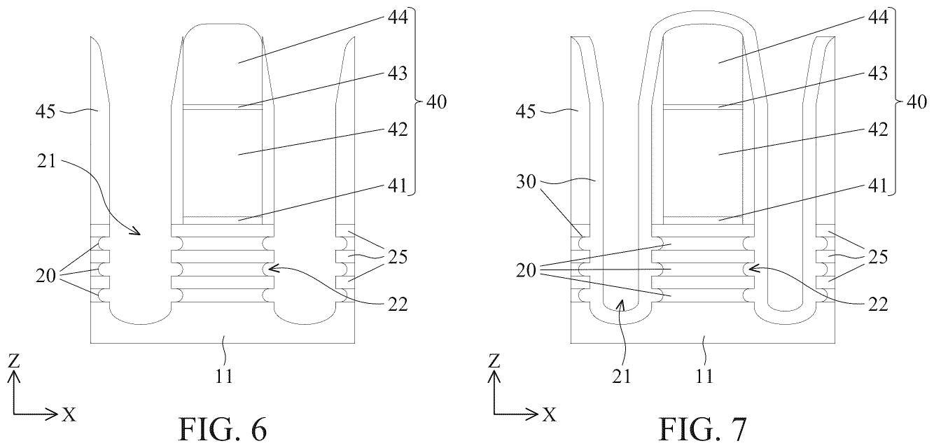

Further, as shown in FIG. 6, the first semiconductor layers 20 are laterally etched in the X direction within the source/drain space 21, thereby forming cavities 22. When the first semiconductor layers 20 are SiGe and the second semiconductor layers 25 are Si, the first semiconductor layers 20 can be selectively etched by using a wet etchant such as, but not limited to, a mixed solution of H₂O₂, CH₃COOH and HF, followed by H₂O cleaning. In some embodiments, the etching by the mixed solution and cleaning by water is repeated 10 to 20 times. The etching time by the mixed solution is in a range from about 1 min to about 2 min in some embodiments. The mixed solution is used at a temperature in a range from about 60 °C to about 90 °C in some embodiments. In some embodiments, other etchants are used.

In some embodiments, the cavity 22 has a curved end shape convex toward the first semiconductor layer 20 (lateral U-shape cross section). In other embodiments, the cavity 22 has a lateral V-shape cross section having an apex at the first semiconductor layer 20.

Next, as shown in FIG. 7, a first insulating layer 30 is formed on the etched lateral ends of the first semiconductor layers 20 and on end faces of the second semiconductor layers 25 in the source/drain space 21 and over the sacrificial gate structure 40. The first insulating layer 30 is conformally formed so that a space is left in the source/drain space 21. The first insulating layer 30 includes one of silicon nitride and silicon oxide, SiON, SiOC, SiCN and SiOCN, or any other suitable dielectric material. The first insulating layer 30 is made of a different material than the sidewall spacers (first cover layer) 45 in some embodiments, and is made of the same material as the sidewall spacers 45 in other embodiments. The first insulating layer 30 can be formed by ALD or any other suitable methods. By forming the first insulating layer 30, the cavities 22 are fully filled with the first insulating layer 30.

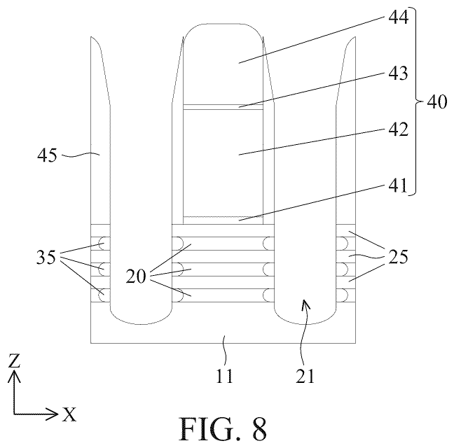

After the first insulating layer 30 is formed, an etching operation is performed to partially remove the first insulating layer 30, thereby forming inner spacers 35, as shown in FIG. 8. In some embodiments, the end face of the inner spacers 35 is recessed more than the end face of the second semiconductor layers 25. The recessed amount is in a range from about 0.2 nm to about 3 nm and is in a range from about 0.5 nm to about 2 nm in other embodiments. In other embodiments, the recessed amount is less than 0.5 nm and may be equal to zero (i.e.—the end face of the inner spacer 35 and the end face of the second semiconductor layers 25 are flush with each other). In some embodiments, before forming the first insulating layer 30, an additional insulating layer having a smaller thickness than the first insulating layer 30 is formed, and thus the inner spacers 35 have a two-layer structure. In some embodiments, widths (lateral length) of the inner spacers 35 are not constant.

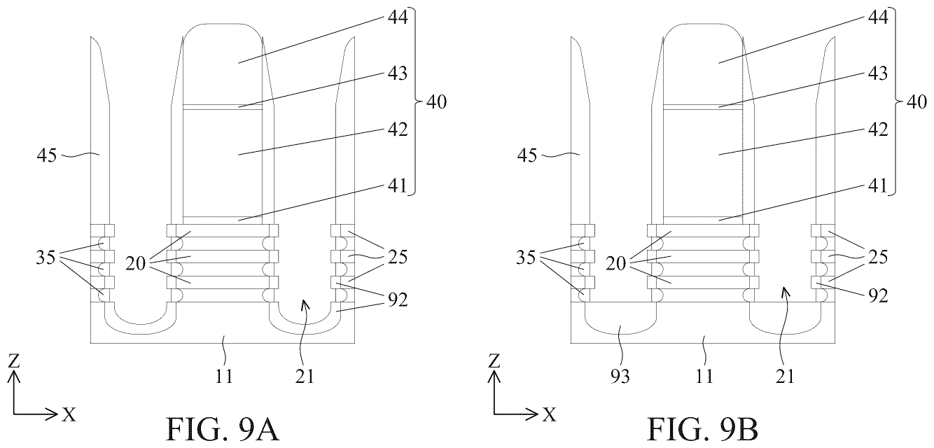

After the inner spacers 35 are formed, a first epitaxial layer 92 is formed on lateral end faces of the second semiconductor layer 25 and the exposed surface of the lower fin structure 11 in some embodiments, as shown in FIG. 9A. In some embodiments, the first epitaxial layer 92 includes Si doped with P or As for an n-type FET and doped with B for a p-type FET. In some embodiments, the dopant concentration of the first epitaxial layer 92 is higher than the dopant concentration of the second semiconductor layers 25. In some embodiments, the dopant concentration of the first epitaxial layer 92 gradually increases from the interface between the first epitaxial layer 92 and the second semiconductor layers 25 or lower fin structure 11 to the source/drain space 21. In some embodiments, the thickness of the first epitaxial layer 92 as deposited is in a range from about 1 nm to about 10 nm. In some embodiments, during the epitaxial formation of the first epitaxial layer 92, some of the dopant elements diffuse into the second semiconductor layer 25 or lower fin structure 11 to a depth of about 0.5 nm to about 2 nm.

In some embodiments, after the inner spacers 35 are formed, a first epitaxial layer 92 is formed on lateral end faces of the second semiconductor layer 25 and an undoped silicon layer 93 is formed the exposed surface of the lower fin structure 11, as shown in FIG. 9B. In some embodiments, the first epitaxial layer 92 includes Si doped with P or As for an n-type FET and doped with B for a p-type FET. The undoped silicon layer may be epitaxially formed. While the silicon layer 93 is formed as an undoped layer, in some embodiments it subsequently becomes an unintentionally doped layer. Dopant from the subsequently formed source/drain structures may diffuse from the source/drain structures into the silicon layer 93. Thus, the silicon layer 93 may be referred to as an unintentionally doped layer.

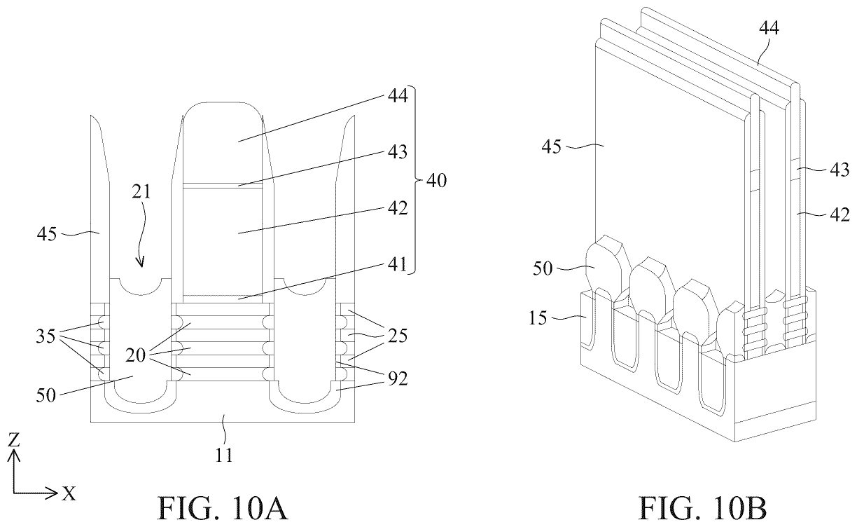

Then, as shown in FIGS. 10A and 10B, source/drain structures 50 are formed in the source/drain space 21. FIG. 10A is a cross section view along the X direction and FIG. 10B is an isometric view of the structure. In some embodiments, source/drain structures 50 include one or more layers of SiC, SiP, SiAs and/or SiCP for an n-type FET. In certain embodiments, SiC or SiCP is used. In some embodiments, the source/drain structure 50 includes SiGe, SiGeSn, Ge, GeSn and/or SiSn for a p-type FET. When SiGe is used, the Ge content is about 60 atomic % to about 80 atomic % in some embodiments. In some embodiments, the source/drain structures 50 are formed by an epitaxial process. In some embodiments, the source/drain structure 50 applies a tensile stress to the second semiconductor layer 25 for an n-type FET and a compressive stress to a p-type FET.

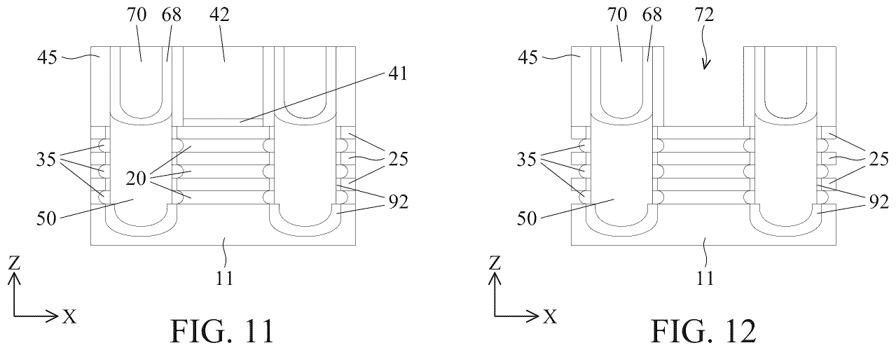

Then, an interlayer dielectric (ILD) layer 70 is formed over the source/drain structure 50 and the sacrificial gate structure 40. In some embodiments, before the ILD layer 70 is formed, a contact etch stop layer 68 is formed. Next, the ILD layer 70 is planarized by chemical mechanical polishing (CMP) to expose the sacrificial gate electrode layer 42, as shown in FIG. 11. The materials for the ILD layer 70 can include compounds comprising Si, O, C, and/or H, such as a silicon oxide, SiCOH, and SiOC. Organic materials, such as a polymer, including polyimide, may be used for the ILD layer 70. Materials for the contact etch stop layer 68 can include a silicon nitride, a silicon oxide, SiCN, SiON, and SiOCN. In some embodiments, the materials for the ILD layer 70 and the etch stop layer 68 are different from each other, and thus have different etch selectivities.

Then, as shown in FIG. 12, the sacrificial gate electrode layer 42 and the sacrificial gate dielectric layer 41 are removed forming a gate space 72. The ILD layer 70 protects the source/drain structures 50 during the removal of the sacrificial gate structures. The sacrificial gate structures can be removed using plasma dry etching and/or wet etching. When the sacrificial gate electrode layer 42 is polysilicon and the ILD layer 70 is silicon oxide, a wet etchant such as a TMAH solution can be used to selectively remove the sacrificial gate electrode layer 42. The sacrificial gate dielectric layer 41 can thereafter be removed using plasma dry etching and/or wet etching.

After the sacrificial gate structures are removed, the first semiconductor layers 20 are removed, thereby forming nanosheets, nanowires, or nanostructures (channel regions) of the second semiconductor layers 25 stacked along the Z-direction, as shown in FIG. 12. The first semiconductor layers 20 can be removed or etched using an etchant that can selectively etch the first semiconductor layers 20 against the second semiconductor layers 25, as set forth above. Since the inner spacers 35 were previously formed, the etching of the first semiconductor layers 20 stops at the inner spacers 35. In other words, the inner spacers 35 may function as an etch-stop layer for etching of the first semiconductor layers 20.

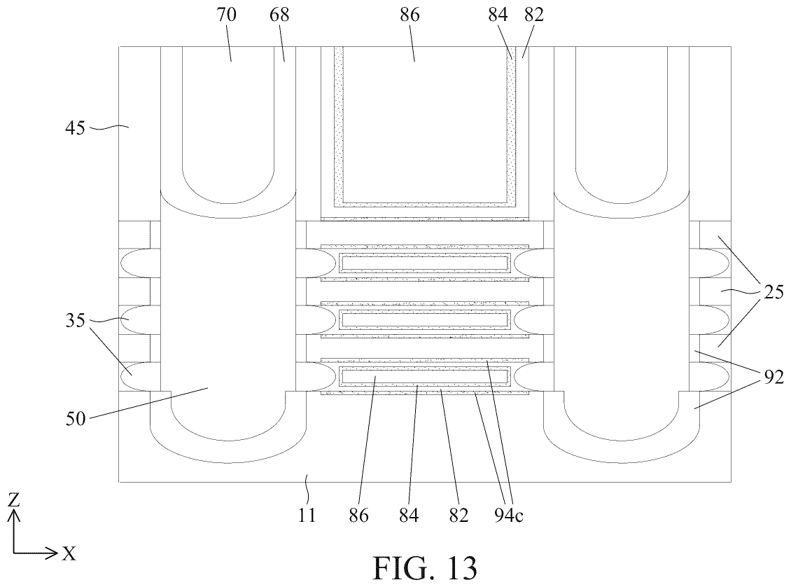

After the semiconductor nanowires or nanosheets (channel regions) of the second semiconductor layers 25 are formed, a metal gate structure is formed as shown in FIG. 13. FIG. 13 is a cross section view along the X direction. In some embodiments, the structure and/or material of the gate electrode for the n-type GAA FET are different from the structure and/or material of the gate electrode for the p-type GAA FET.

In certain embodiments, the gate dielectric layer 82 includes one or more layers of a dielectric material, such as silicon oxide, silicon nitride, or high-k dielectric material, other suitable dielectric material, and/or combinations thereof. In some embodiments of the disclosure, the high-k dielectric materials have a dielectric constant greater than about 7. Examples of high-k dielectric material include HfO₂, HfSiO, HfSiON, HfTaO, HfTiO, HfZrO, zirconium oxide, aluminum oxide, titanium oxide, yttrium oxide, yttrium silicon oxide, hafnium dioxide-alumina (HfO₂—Al₂O₃) alloy, other suitable high-k dielectric materials, and/or combinations thereof. In some embodiments, an interfacial layer 94c including a metal silicate is formed between the channel layers 25 and the gate dielectric layer 82. The formation of the metal silicate containing interfacial layer 94c will be described in more detail infra.

The gate dielectric layer 82 may be formed by CVD, ALD or any suitable method. In one embodiment, the gate dielectric layer is formed using a highly conformal deposition process such as ALD in order to ensure the formation of a gate dielectric layer having a uniform thickness around each channel layer. The thickness of the gate dielectric layer 82 is in a range from about 1 nm to about 6 nm in one embodiment.

In some embodiments, the metal gate structure includes one or more work function adjustment layers 84 disposed over the gate dielectric layer 82. The work function adjustment layers 84 are made of a conductive material such as a single layer of TiN, TaN, TaAlC, TiC, TaC, Co, Al, TiAl, HfTi, TiSi, TaSi or TiAlC, or a multilayer of two or more of these materials. In some embodiments, one or more of TiAlC, Al, TiAl, TaN, TaAlC, TiN, TiC and Co are used as the work function adjustment layer for the p-channel FET. For an n-channel FET, one or more of TaN, TaAlC, TiN, TiC, Co, TiAl, HfTi, TiSi and TaSi is used as the work function adjustment layer, according to some embodiments. The work function adjustment layer may be formed by ALD, PVD, CVD, e-beam evaporation, or other suitable process. Further, the work function adjustment layer may be formed separately for the n-channel FET and the p-channel FET which may use different metal layers.

The gate electrode layer 86 is formed on the work function adjustment layer 84 if present or on the gate dielectric layer 82 to surround each channel layer. The gate electrode layer 86 includes one or more layers of conductive material, such as polysilicon, aluminum, copper, nickel, titanium, tantalum, tungsten, cobalt, molybdenum, tantalum nitride, nickel silicide, cobalt silicide, TiN, WN, TiAl, TiAlN, TaCN, TaC, TaSiN, TiSiN, WCN, TiWN, metal alloys, other suitable materials, and/or combinations thereof.

The gate electrode layer 86 may be formed by CVD, ALD, electro-plating, or other suitable method. The gate electrode layer 86 is also deposited over the upper surface of the ILD layer 70. The gate dielectric layer, work function adjustment layer, and the gate electrode layer formed over the ILD layer 70 are then planarized by using, for example, CMP, until the top surface of the ILD layer 70 is revealed. In some embodiments, after the planarization operation, the gate electrode layer is recessed and a cap insulating layer (not shown) is formed over the recessed gate electrode. In some embodiments, the cap insulating layer includes one or more layers of a silicon nitride-based material, such as silicon nitride. The cap insulating layer is formed by depositing an insulating material followed by a planarization operation.

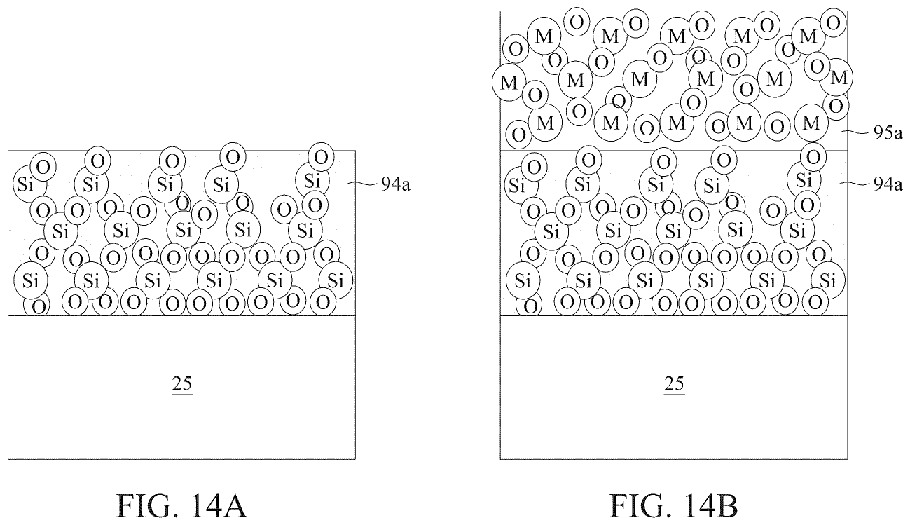

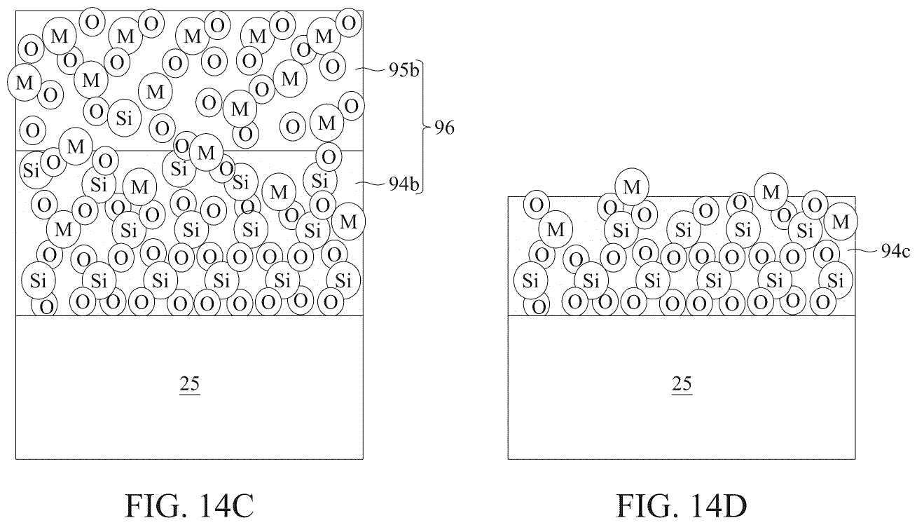

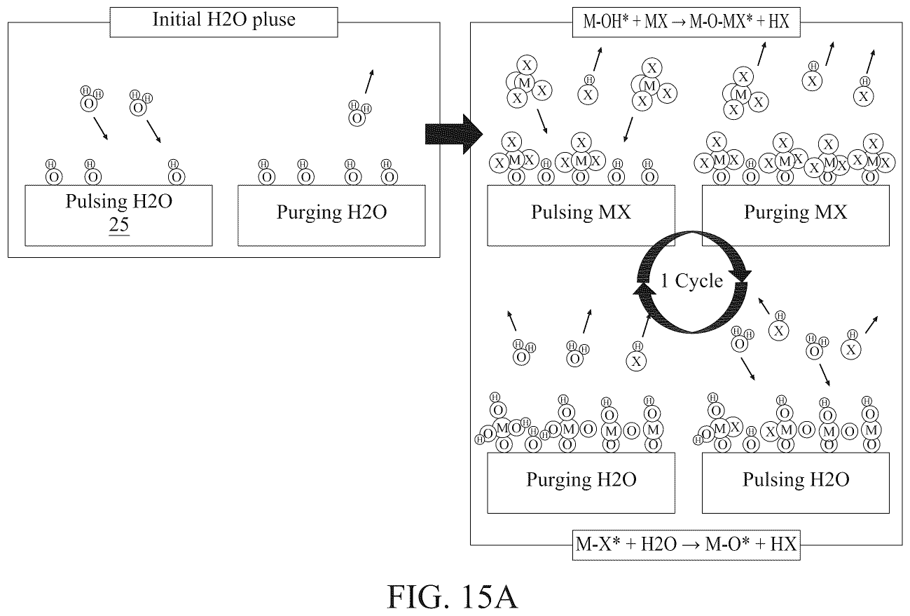

FIGS. 14A to 14D are schematic illustrations showing the formation of the metal silicate containing interfacial layer 94c over the channel regions 25 according to embodiments of the present disclosure.

In some embodiments, an interfacial layer 94a is formed over exposed portions of the channel region 25 (or semiconductor layers, nanosheets, or nanostructures), as shown in FIG. 14A. FIG. 14A is a detailed view of a portion of the channel region 25/interfacial layer 94a interface. While the interfacial layer 94a is shown disposed over one surface of the channel region 25, it is understood the interfacial layer 94a surrounds an upper surface and opposing side surfaces of the channel region in FinFET devices, and wraps around the nanosheets of GAA FET devices. The interfacial layer 94a comprises a silicon oxide in some embodiments. The interfacial layer 94a can be formed by thermal oxidation, steam, or a chemical oxidation in some embodiments. In some embodiments, the interfacial layer 94a is formed by an RCA-1 cleaning operation (a solution comprising water, ammonium hydroxide, and hydrogen peroxide). In other embodiments, the interfacial layer 94a is formed by a deposition operation, such as a CVD operation.

A metal-containing layer 95a is subsequently formed over the interfacial layer 94a, as shown in FIG. 14B. The metal-containing layer 95a is made of a metal oxide in some embodiments, but is not limited to metal oxides. In some embodiments, the metal-containing layer is made of one or more elemental metals, metal alloys, or a metal nitride. In some embodiments, the metal-containing layer 95a includes one or more metals selected from the group consisting of Al, Ga, Gd, Hf, La, Lu, Nd, Pr, Ta, Ti, Tm, Y, and Zr. In some embodiments, the metal containing layer 95a is formed by deposition process, such as atomic layer deposition, chemical vapor deposition, sputtering, or plating

The metal-containing layer 95a and interfacial layer 94a are heated to cause a reaction between the metal in the metal-containing layer 95a and silicon in the interfacial layer 94a to form a metal silicate layer. In some embodiments, metal diffuses from the metal-containing layer 95a into the interfacial layer 94a, and silicon diffuses from the interfacial layer 94a into the metal-containing layer 95a during the heating operation, thereby forming a metal silicate layer 96 including a metal-containing layer 95b including silicon and an interfacial layer 94b including the metal, as shown in FIG. 14C. In some embodiments, the heating is performed by a rapid thermal annealing (RTA) operation.

The metal-containing layer 95b including silicon is subsequently removed by an etching operation, as shown in FIG. 14D. An interfacial layer 94c including the metal remains over the channel region 25 after the etching operation. In some embodiments, the etching operation is a wet etching operation. In some embodiments, the etching operation is performed using an RCA clean operation including sequential standard clean 1 (SC1) (H₂O, H₂O₂, and NH₄OH solution) and standard clean 2 (SC2) (H₂O, H₂O₂, and HCl solution) operations. The chemical components of the RCA clean operation have high etching metal oxide to silicon dioxide selectivity. In some embodiments, the etching operation also removes a portion of the interfacial layer 94b including the metal silicate. Thus, the final interfacial layer 94c including the metal silicate or (metal silicate layer 94c) is thinner than the initially formed interfacial layer 94a in some embodiments. In some embodiments, the metal silicate layer 94c has a higher dielectric constant k than the initially formed interfacial layer 94a. In some embodiments, a concentration of the metal in the metal silicate layer 94c ranges from about 25 ppm to about 2 at. %. In some embodiments, the concentration of the metal in the metal silicate layer 94c ranges from about 50 ppm to about 1 at. %.

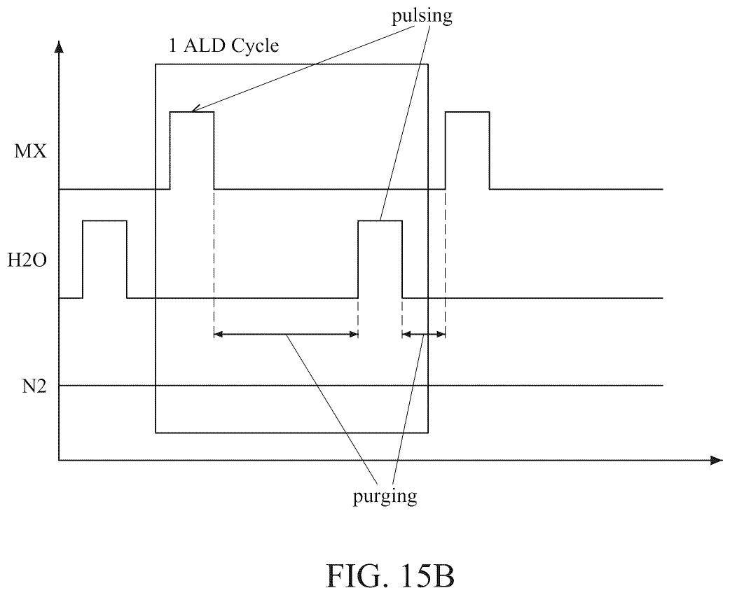

FIG. 15A shows an atomic layer deposition operation according to embodiments of the present disclosure. In this example, a metal oxide layer is formed over the channel region 25 by a series of operations. An initial H₂O pulse to form a single layer on the channel region is followed by an H₂O purging. The one or more cycles of pulsing and purging of a gaseous metal compound and pulsing and purging of H₂O to form a desired number of layers of a metal oxide are performed. FIG. 15B shows an atomic layer deposition gas supply profile according to embodiments of the present disclosure. In particular, the gas supply profile of the gaseous metal compound, water, and nitrogen carrier gas is shown.

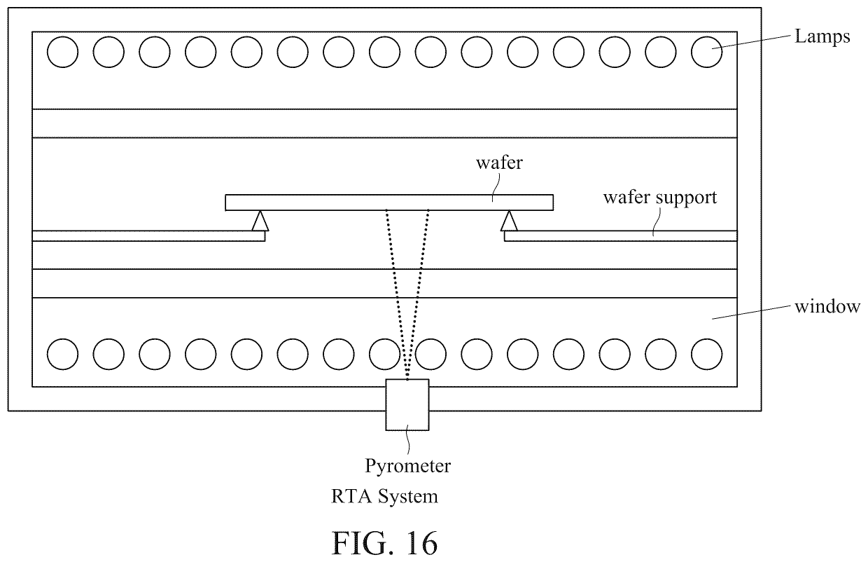

FIG. 16 shows a schematic view of a rapid thermal annealing (RTA) operation according to embodiments of the present disclosure. RTA is used to cause the metal in the metal-containing layer 95a and the silicon in the interfacial layer 94a to diffuse and react to form the metal silicate layer 96. High intensity infrared lamps or lasers are used to rapidly heat the interfacial layer 94a and metal-containing layer 95a to a temperature of about 300 °C to about 700 °C in some embodiments. The RTA is performed under vacuum or in an inert ambient, such as a nitrogen or argon ambient. A pyrometer is used in some embodiments to measure the temperature of the substrate and to control the duration and temperature of the RTA.

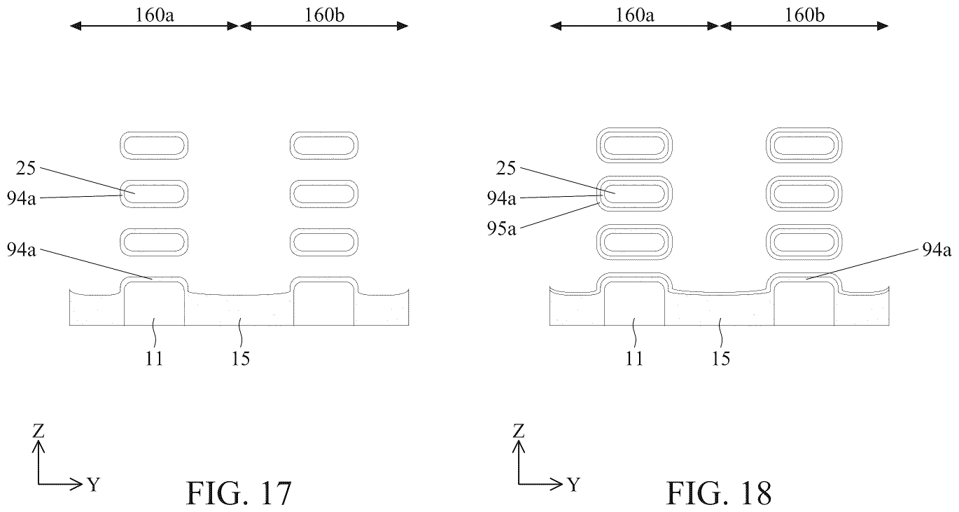

FIGS. 17 to 34 show cross sectional views of various stages of manufacturing a GAA FET semiconductor device according to embodiments of the present disclosure. It is understood that additional operations can be provided before, during, and after the processes shown by FIGS. 17-34, and some of the operations described below can be replaced or eliminated, for additional embodiments of the method. The order of the operations/processes may be interchangeable.

FIG. 17 shows the formation of an interfacial layer 94a over a channel region 25. The interfacial layer 94a may be formed by any suitable technique including those disclosed herein. A GAA FET structure is illustrated in FIGS. 17-34, but other structures, including FinFETs and planar FETs are within the scope of this disclosure. In cases where the device is a GAA FET, the interfacial layer 94a surrounds the nanosheet or nanostructure 25. The GAA FET, as shown in FIGS. 17-34, includes two multilayer stacks of nanosheets, but the GAA FET has one multilayer stack of nanosheets or more than two multilayer stacks of nanosheets in other embodiments. The first multilayer stack is in a first region 160a and the second multilayer stack is in a second region 160b. In some embodiments, the interfacial layer 94a has a thickness of about 0.3 nm to about 3 nm. In other embodiments, the interfacial layer 94 a has a thickness of about 0.5 nm to about 1.5 nm.

A metal-containing layer 95a is subsequently formed over the interfacial layer 94a, as shown in FIG. 18. The metal-containing layer 95a may be a pure elemental layer, an alloy, a metal oxide layer, or a metal nitride layer formed by suitable technique as disclosed herein. The metal may include one or more of the metals disclosed herein. In some embodiments, the metal-containing layer 95a is a metal oxide layer formed by atomic layer deposition at a temperature ranging from about 150 °C to about 450 °C. In cases where the semiconductor device structure is a GAA FET, the metal-containing layer 95a wraps around the interfacial layer 94a. In some embodiments, the metal-containing layer 95a is also formed over the isolation insulating layer 15 between the multilayer stacks of nanosheets.

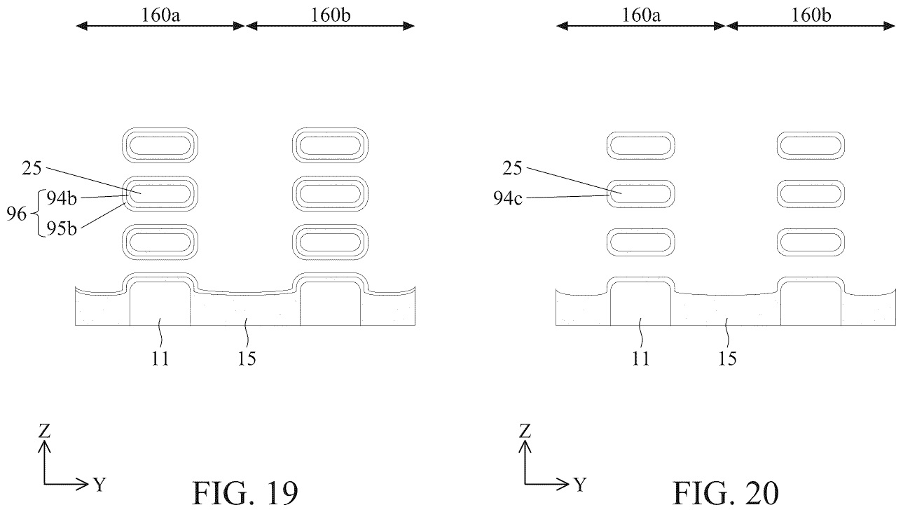

The metal-containing layer 95a and the interfacial layer 94a are subsequently heated to react the metal in the metal-containing layer 95a and silicon in the interfacial layer 94a to form a metal silicate layer 96, as disclosed herein in reference to FIG. 14C, and shown in FIG. 19. During the heating, metal in the metal-containing layer 95a diffuses into the interfacial layer 94a to form an interfacial layer 94b including the metal and silicon from the interfacial layer diffuses into the metal-containing layer to form a metal-containing layer including the silicon. Thus, the metal silicate layer 96 includes a metal-containing layer 95b including silicon and the interfacial layer 94b including the metal. In some embodiments, the heating is performed by a rapid thermal annealing (RTA) operation, as disclosed herein.

Then, as shown in FIG. 20, a portion of the metal silicate layer 96 is removed to produce an interfacial layer 94c including a metal silicate disposed over the nanosheet 25. The portion of the metal silicate layer may be removed by wet or dry etching. In some embodiments, a wet etching operation using the RCA clean operation including sequential SC1 and SC2 operations is performed, as disclosed herein with reference to FIG. 14D. The final interfacial layer 94c including the metal silicate or (metal silicate layer 94c) is thinner than and has a higher dielectric constant k than the initially formed interfacial layer 94a in some embodiments. In some embodiments, the thinner, higher k metal silicate layer 94c also remains over the isolation insulating layer 15. In some embodiments, the metal concentration in the metal silicate layer 94c formed over the isolation insulating layer 15 is the same as the metal concentration in metal silicate layer 94c formed over the channel regions 25.

In some embodiments, the interfacial layer 94c including the metal silicate has a thickness of about 0.3 nm to about 3 nm. In other embodiments, the interfacial layer 94c including the metal silicate has a thickness of about 0.5 nm to about 1.5 nm. In other embodiments, the interfacial layer 94c including the metal silicate has a thickness of about 0.7 nm to about 1.2 nm. Thicknesses of the interfacial layer 94c including the metal silicate outside the disclose ranges may suffer from decreased device performance at thicknesses greater than the disclosed ranges and increased current leakage at thicknesses below the disclosed ranges.

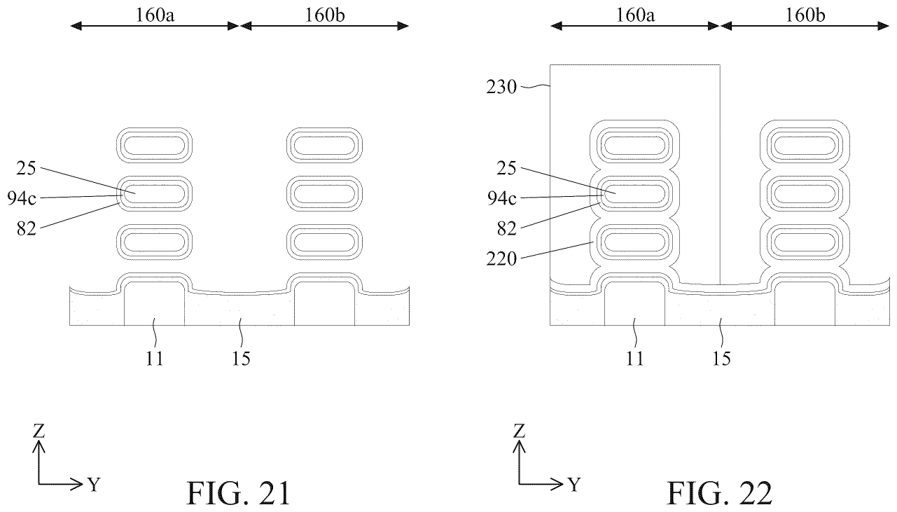

In some embodiments, a gate dielectric layer 82 is subsequently formed over the interfacial layer 94c including the metal silicate, as shown FIG. 21. The gate dielectric layer 82 is made of and formed by the gate dielectric materials and techniques disclosed herein. In some embodiments, the gate dielectric layer is made of a high-k material, and has a thickness ranging from about 0.5 nm to about 5 nm. In other embodiments, the gate dielectric layer thickness ranges from about 1 nm to about 2.5 nm.

In some embodiments, a hard mask layer 220 and a second mask layer 230 are formed over the first region 160a of the semiconductor device structure, as shown in FIG. 22. In some embodiments, the hard mask layer 220 is a nitride or an oxide layer conformally formed over the gate dielectric layer 82, and the second masked layer 230 is a carbon or organic material-based layer formed over the hard mask layer 220. In some embodiments, the hard mask layer is formed by CVD or ALD. In some embodiments, the second mask layer 230 is a bottom anti-reflective coating (BARC) layer, a photoresist layer, or a spin-on carbon layer. In some embodiments, the hard mask layer 220 and the second mask layer 230 are formed over the surface of both the first and second regions 160a, 160b and then removed from over the second region 160b using photolithographic and/or etching techniques.

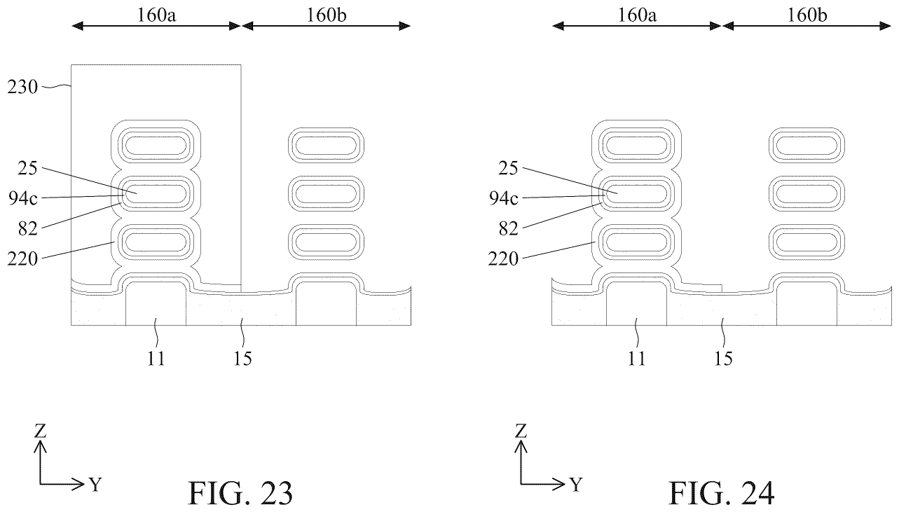

The hard mask 220 is subsequently removed in the second region 160b by etching using a suitable etchant selective to the hard mask material in some embodiments, as shown in FIG. 23. Then, the second mask layer 230 is removed in the first region using a suitable technique, such as plasma ashing or a photoresist stripping, as shown in FIG. 24.

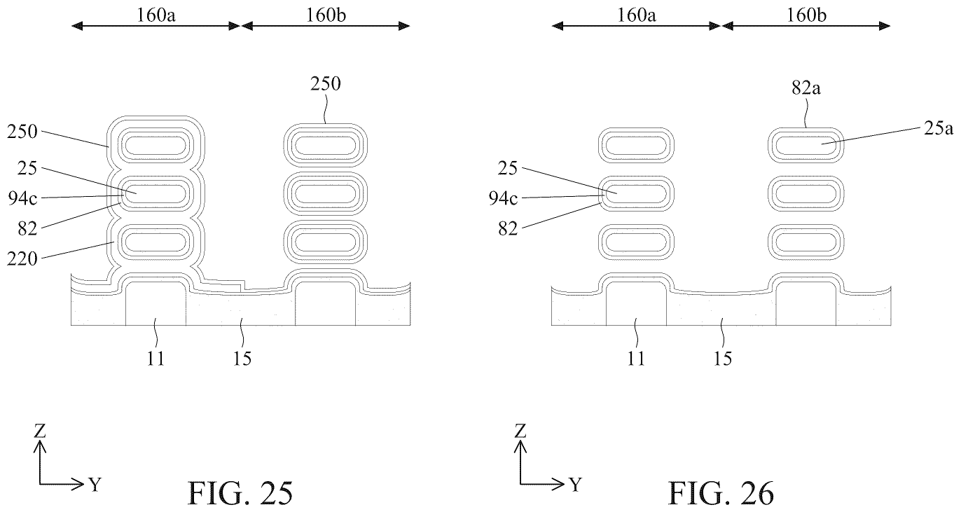

In some embodiments, it is desirable to tune the threshold voltage (Vₜ) of the gate electrode. Different threshold voltages can be obtained by forming a dipole layer over the channel region of one or more regions of the semiconductor device and not over other regions. For example, as shown in FIG. 25, a dipole layer 250 is formed over the dielectric layer 82 in the second region 160b and over the hard mask layer 220 in the first region 160a. In some embodiments, the dipole layer 250 includes one or more selected from the group consisting of Al₂O₃, CaO, Ga₂O₃, La₂O₃, Lu₂O₃, MgO, ScO₂, Y₂O₃, and ZnO. After forming the dipole layer 250, the semiconductor device structure is heated to diffuse the dipole layer material into the gate dielectric layer 82 and the channel region 25 of the second region 160b thereby forming a doped gate dielectric layer 82a and a doped channel region 25a doped with the dipole layer material in the second region. The hard mask layer 220 prevents the dipole layer material from being diffused into the dielectric layer 82 and channel region 25 of the first region 160a. In some embodiments, the structure is heated by a rapid thermal anneal (RTA) operation disclosed herein. After diffusing the dipole layer material into the gate dielectric layer and the channel region of the second region, the dipole layer 250 and hard mask layer 220 are removed from the first region 160a by a suitable etching operation, as shown in FIG. 26 in some embodiments. Any remaining dipole layer 250 in the second region may also be removed by the etching operation.

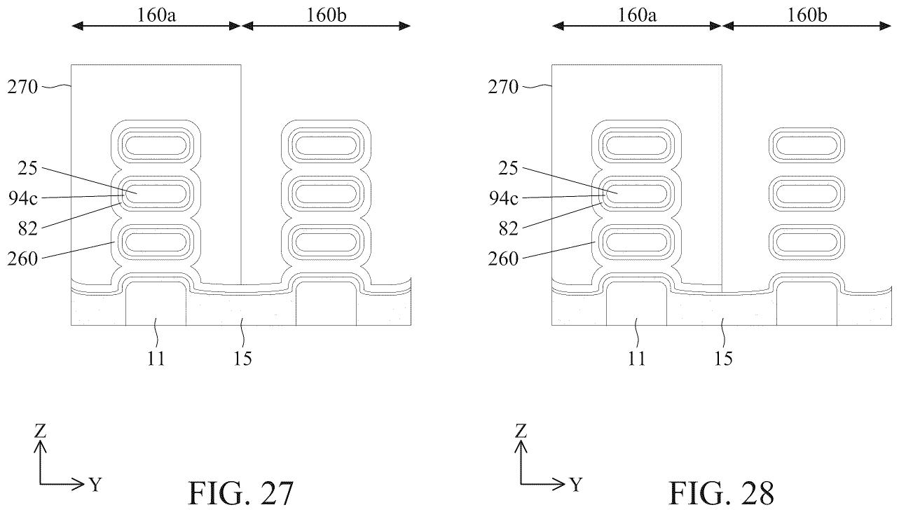

In some embodiments, a second hard mask layer 260 and a third mask layer 270 are formed over the semiconductor device structure in some embodiments. The second hard mask layer 260 and the third mask layer 270 may be made of the same materials and may be formed by the same operations as the hard mask layer 220 and second mask layer 230 disclosed herein in reference to FIG. 22. Then, the third mask layer 270 is removed in the second region as shown in FIG. 27, and as disclosed herein in reference to FIG. 22.

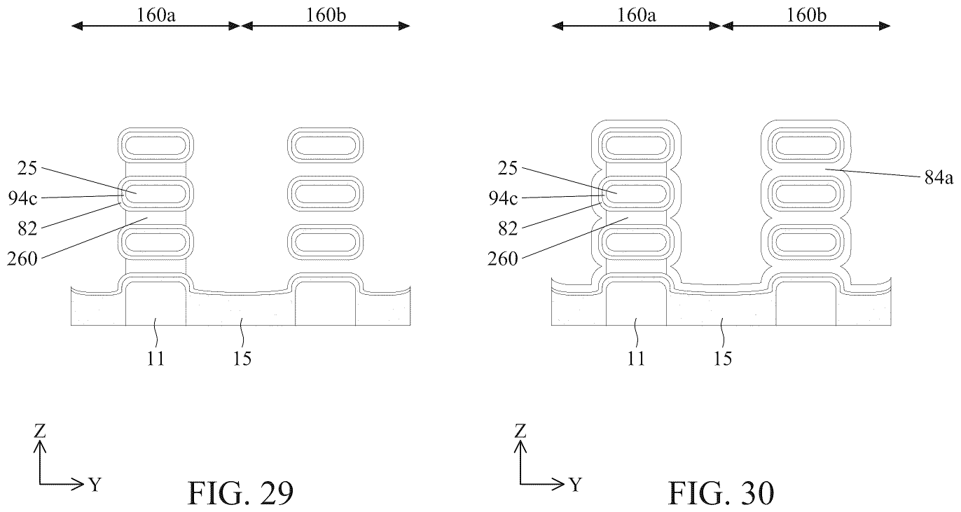

In some embodiments, the second hard mask layer 260 is removed in the second region 160b, as shown in FIG. 28. The second hard mask layer 260 may be removed by a suitable etching technique, as disclosed herein. In some embodiments, after removing the second hard mask layer in the second region 160b, the third mask layer 270 is removed in the first region 160a, and a portion of the second hard mask layer 260 is removed in the first region 160a, as shown in FIG. 29. The third mask layer 270 may be removed by a suitable resist stripping operation or by plasma ashing in some embodiments, and the portion of the second hard mask layer 260 is removed by a suitable etching operation. As shown in FIG. 29, in some embodiments where the semiconductor device is a GAA FET, a portion of the second hard mask layer 260 between the channel layer 25 remains after the etching operation.

In some embodiments, a first work function adjustment layer 84a is formed over the gate dielectric layer 82, as shown in FIG. 30. The first work function adjustment layer 84a is made of a conductive material such as a single layer of TiN, TaN, TaAlC, TiC, TaC, W, Co, Al, Ni, Ti, TiAl, TiSiN, HfTi, TiSi, TaSi, TiAlC, TiSiN, WCN, TiWN, Ta, TaN, or WN. The first work function adjustment layer may be formed by ALD, PVD, CVD, e-beam evaporation, or other suitable process. In some embodiments, the first work function adjustment layer has a varying thickness over the various nanosheets. For example, in some embodiments, the first work function adjustment layer has a thickness in the range of about 1.5 nm to about 4.0 nm over outer nanosheets and a thickness in the range of about 3.0 nm to about 6.0 nm over inner nanosheets in the multilayer nanosheet stacks.

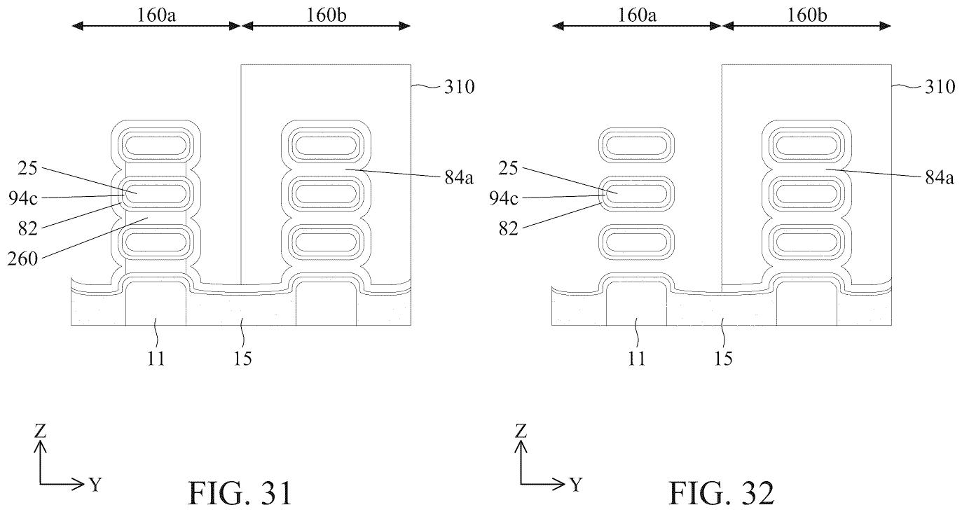

A fourth mask layer 310 is formed over the first work function adjustment layer 84a in some embodiments. In some embodiments, the fourth mask layer 310 is removed from the first region 160a, as shown in FIG. 31. The fourth mask layer 310 may be made of any of the materials disclosed herein for the second mask layer 230 and the third mask layer 270. The portions of the fourth mask layer removed from the first region 160a may be removed by any of the techniques disclosed herein for removing the second mask layer 230 and the third mask layer 270. In some embodiments, the first work function adjustment layer 84a and any remaining second hard mask layer 260 are removed from the first region 160a of the semiconductor device structure, as shown in FIG. 32. The first work function adjustment layer 84a and any remaining second hard mask layer 260 are removed using suitable etching operations.

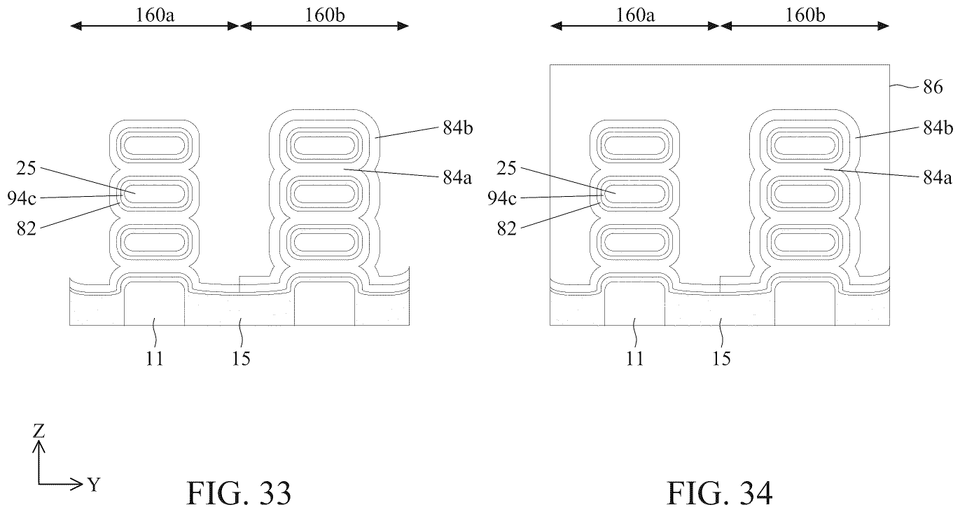

The fourth mask layer 310 is removed from the second region 160b using any of the suitable techniques for removing the second or third mask layers 230, 270. In some embodiments, after removing the fourth mask layer, a second work function adjustment layer 84b is formed over the semiconductor device structure, as shown in FIG. 33. In the embodiment shown in FIG. 33, the multilayer stack of nanosheets in the first region 160a includes the first work function adjustment layer 84a, while the multilayer stack of nanosheets in the second region 160b includes the first work function adjustment layer 84a and the second work function adjustment layer 84b. The first work function adjustment layer 84a and the second work function adjustment layer 84b are made of different materials. In some embodiments, the second work function adjustment layer 84b is made of TiAl, TiAlN, TiAlC, TiC, TaAlC, or TaC. The second work function adjustment layer may be formed by ALD, PVD, CVD, e-beam evaporation, or other suitable process. In some embodiments, second work function layers have a thickness of about 1.5 nm to about 4.0 nm over outer nanosheets and a thickness in the range of about 3.0 nm to about 6.0 nm over nanosheets in the multilayer nanosheet stacks.

As shown in FIG. 34, a gate electrode layer 86 is formed over the work function adjustment layers 84a, 84b. As disclosed herein, the gate electrode layer 86 includes one or more layers of conductive material, such as polysilicon, aluminum, copper, nickel, titanium, tantalum, tungsten, cobalt, molybdenum, tantalum nitride, nickel silicide, cobalt silicide, TiN, WN, TiAl, TiAlN, TaCN, TaC, TaSiN, TiSiN, WCN, TiWN, metal alloys, other suitable materials, and/or combinations thereof. And the gate electrode layer 86 may be formed by CVD, ALD, electro-plating, or other suitable method.

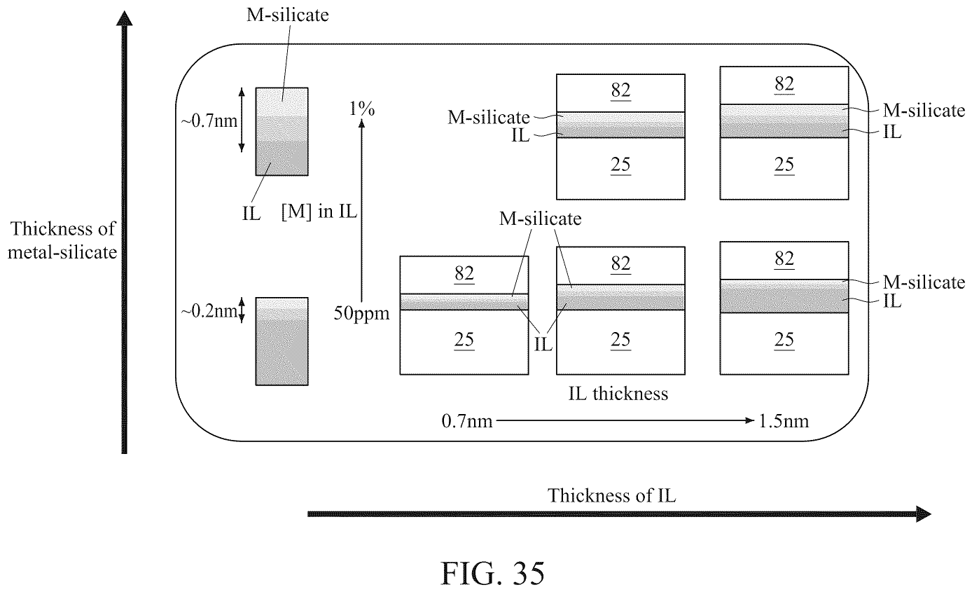

FIG. 35 illustrates detailed cross sectional views of the gate dielectric layer/metal-containing layer/semiconductor layer interface according to various embodiments of the present disclosure. The relationship between the thickness of the interfacial layer (IL) and the thickness of the metal silicate layer (M-silicate) is illustrated. In some embodiments, the thickness of the interfacial layer ranges from about 0.7 nm to about 1.5 nm, while the thickness of metal silicate-containing portion of the interfacial layer 0.2 nm to about 0.7 nm. In some embodiments, the metal concentration [M] in the interfacial layer IL increases as the thickness of the metal-silicate containing portion increases of the interfacial layer increases. As shown in FIG. 35, the metal concentration [M] increases from about 50 ppm to about 1 at. % as the thickness of the metal-containing portion [M-silicate] increases from about 0.2 nm to about 0.7 nm in some embodiments.

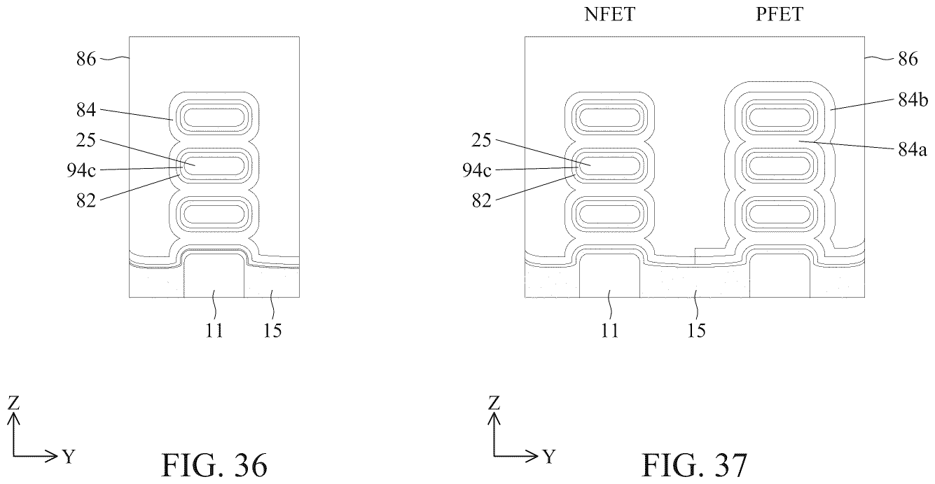

FIG. 36 shows a cross sectional view of a GAA FET semiconductor device according to an embodiment of the present disclosure. In some embodiments, the single work function adjustment layer 84 is formed between the gate dielectric layer 82 and the gate electrode layer 86 in either an n-type FET or a p-type FET. In some embodiments, the work function adjustment layer 84 is made of any of the materials disclosed herein for the first work function adjustment layer 84a and the second work function adjustment layer 84b. In some embodiments, a single work function adjustment layer 84 is formed after diffusing a suitable dipole layer material into the dielectric layer 82 to tune the Vt, as disclosed herein with reference to FIGS. 25 and 26. In some embodiments, a single work function adjustment layer 84 is formed in both an n-type FET and a p-type FET of a complementary metal oxide semiconductor (CMOS) device after a different dipole layer material is diffused into the dielectric layer in the n-type FET and the p-type FET to provide a different Vt for each FET.

FIG. 37 shows a cross sectional view of a GAA FET semiconductor device according to an embodiment of the present disclosure. In some embodiments, an n-type FET (NFET) is formed in one region of the semiconductor device structure and a p-type FET (PFET) is formed in another region of the semiconductor device structure. The NFET may have different work function adjustment layers than the PFET. For example, as shown in FIG. 37, the NFET includes a single work function adjustment layer, the second work function adjustment layer 84b, while the PFET includes the first work function adjustment layer 84a and the second work function adjustment layer 84b disposed over the first work function adjustment layer 84a. The work function adjustment layers 84a, 84b may be made of any of the materials disclosed herein for the work function adjustment layers.

In some embodiments, the semiconductor device structure shown in FIG. 34 is formed without the steps of forming the dipole layer. In some embodiments, the semiconductor device structure shown in FIG. 34 is formed without the steps of forming the hard mask layer 260 and removing a portion of the hard mask layer 260 shown in FIGS. 27-31. In other words, the work function adjustment layers 84a, 84b are formed over the gate dielectric layers 82 without the intervening steps shown in FIGS. 27-31.

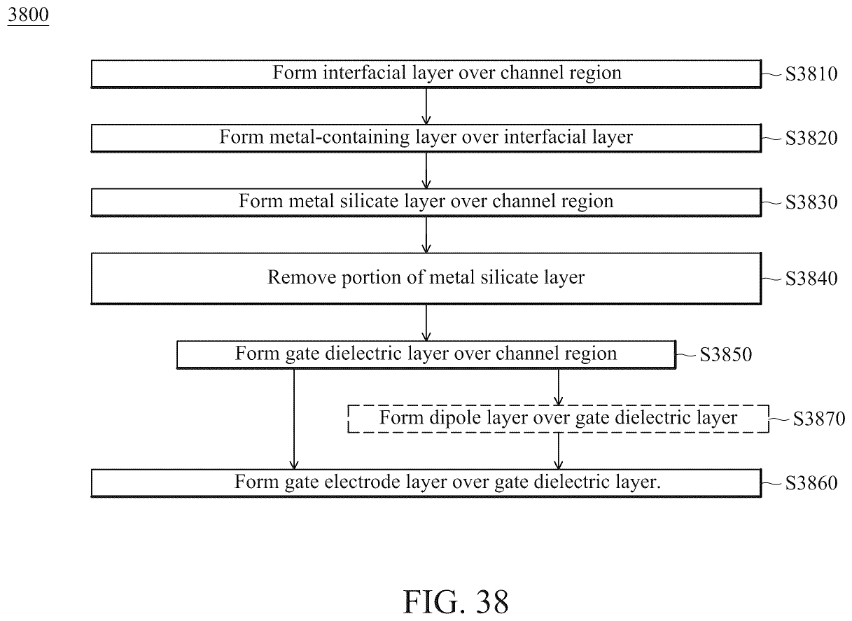

FIG. 38 shows a flow chart for a method 3800 of manufacturing a semiconductor device according to embodiments of the present disclosure. The method of manufacturing a semiconductor device includes an operation S3810 of forming an interfacial layer 94a over a channel region 25. A metal-containing layer 95a is formed over the interfacial layer 94a in operation S3820. Then, in operation S3830, a metal silicate layer 96 is formed over the channel region 25. The metal silicate layer 96 is formed by a heating operation, such as a rapid thermal anneal. A portion of the metal silicate layer 96 is removed in operation S3840. A suitable etching operation is performed to remove the portion of the metal silicate layer 96. In operation S3850, a gate dielectric layer 82 is formed over the channel region 25. The gate dielectric layer 82 is formed over the portion of the metal silicate layer 94c that remains over the channel region 25 after the removing a portion of the metal silicate layer 96. A gate electrode layer 86 is formed over the gate dielectric layer 82 in operation S3860. In some embodiments, a dipole layer 250 is formed over the gate dielectric layer 82 in operation S3870 before forming the gate electrode layer 86.

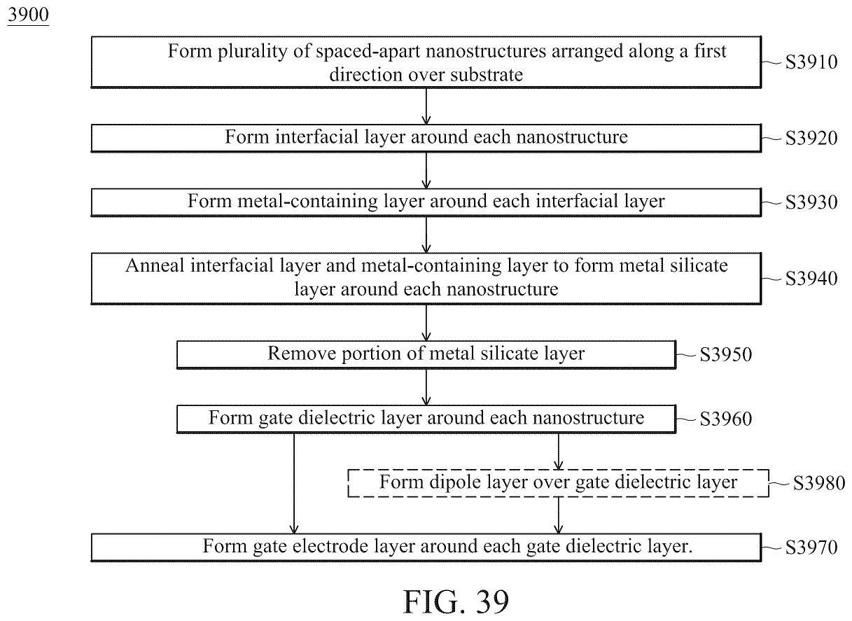

FIG. 39 shows a flow chart for a method 3900 of manufacturing a semiconductor device according to embodiments of the present disclosure. The method of manufacturing a semiconductor device includes an operation S3910 of forming a plurality of spaced-apart nanostructures 25 arranged along a first direction over a substrate 10. An interfacial layer 94a is formed around each of the nanostructures 25 in operation S3920. A metal-containing layer 95a is formed around each of the interfacial layers 94a in operation S3930. In operation S3940, the interfacial layer 94a and the metal-containing layer 95a are annealed to form a metal silicate layer 96 around each of the nanostructures 25. A portion of the metal silicate layer 96 is removed in operation S3950. A gate dielectric layer 82 is formed around each of the nanostructures 25 after removing a portion of the metal silicate layer 96 in operation S3960, and in operation S3970, a gate electrode layer 86 is formed around each of the gate dielectric layers 82. In some embodiments, the method includes forming a dipole layer 250 over the gate dielectric layer 82 in operation S3980 before forming the gate electrode layer 86.

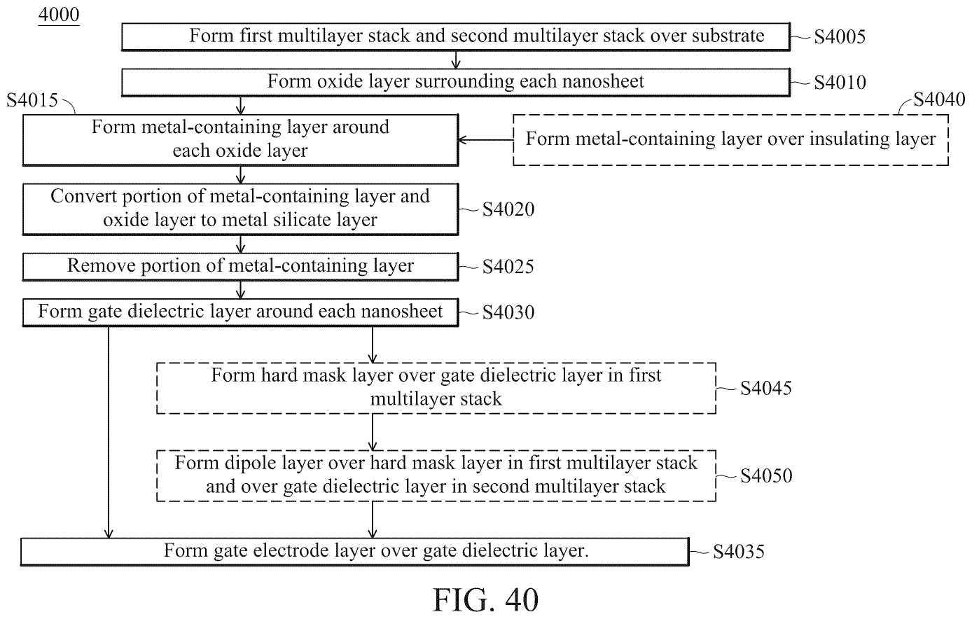

FIG. 40 shows a flow chart for a method 4000 of manufacturing a semiconductor device according to embodiments of the present disclosure. The method of manufacturing a semiconductor device includes an operation S4005 of forming a first multilayer stack and a second multilayer stack over a substrate 10. The first and second multilayer stacks are spaced apart from each other along a first direction. An insulating layer 15 is disposed between the spaced apart first and second multilayer stacks, and the first and second multilayer stacks include a plurality of spaced apart nanosheets 25 arranged along a second direction perpendicular to the first direction. An oxide layer 94a is formed surrounding each of the nanosheets in operation S4010. A metal-containing layer 95a is formed surrounding each of the oxide layers 94a in operation S4015. In operation S4020, a portion of the metal-containing layer 95a and the oxide layer 94a is converted to a metal silicate layer 94b, 95b. A portion of the metal-containing layer 94b, 95b is removed in operation S4025. A gate dielectric layer 82 is formed surrounding each of the nanosheets 25 after removing the portion of the metal-containing layer in operation S4030, and in operation S4035, a gate electrode layer 86 is formed surrounding each of the gate dielectric layers 82. In some embodiments, the method includes an operation S4040 of forming the metal-containing layer 95a over the insulating layer 15. In some embodiments, the method includes an operation S4045 of forming a hard mask layer 220 over the gate dielectric layer 82 in the first multilayer stack before forming the gate electrode layer 86. In some embodiments, the method includes an operation S4050 of forming a dipole layer 250 over the hard mask layer 220 in the first multilayer stack and over the gate dielectric layer 82 in the second multilayer stack before forming the gate electrode layer 86.

Additional operations may be performed on the structure of FIGS. 13, 34, 36, and 37 including forming electrical contacts to the gate electrodes and source/drain regions, including silicide layers. Additional insulating layers and metal wiring layers, including interconnects and vias may be formed over the structure of FIGS. 13, 34, 36, and 37. The structures of FIGS. 13, 34, 36, and 37 may be part of a larger integrated circuit, including additional devices and components.

In embodiments of the disclosure, the thickness of interfacial layers between the gate dielectric layer and the channel regions of a FET are reduced, thereby reducing the capacitance equivalent thickness without increasing current leakage, and the dielectric constant of the interfacial layer is increased, thereby improving performance of the FET device can be improved. Embodiments of the disclosure also allow localized control of the voltage threshold Vt of various transistors in semiconductor device.

It will be understood that not all advantages have been necessarily discussed herein, no particular advantage is required for all embodiments or examples, and other embodiments or examples may offer different advantages.

An embodiment of the disclosure is a method of manufacturing a semiconductor device including forming an interfacial layer over a channel region and forming a metal-containing layer over the interfacial layer. A metal silicate layer is formed over the channel region after forming the metal-containing layer. A portion of the metal silicate layer is removed. A gate dielectric layer is formed over the channel region after removing the portion of the metal silicate layer, and a gate electrode layer is formed over the gate dielectric layer. In an embodiment, the metal-containing layer includes a metal oxide or a metal nitride. In an embodiment, the forming a metal silicate layer includes annealing the interfacial layer and the metal-containing layer. In an embodiment, the metal-containing layer is formed by atomic layer deposition. In an embodiment, the metal-containing layer includes one or more metals selected from the group consisting of Al, Ga, Gd, Hf, La, Lu, Nd, Pr, Ta, Ti, Tm, Y, and Zr. In an embodiment, the gate dielectric layer includes one or more selected from the group consisting of hafnium oxide, zirconium oxide, aluminum oxide, hafnium zirconium oxide, yttrium oxide, and yttrium silicon oxide. In an embodiment, the method includes forming a dipole layer over the gate dielectric layer before forming the gate electrode layer. In an embodiment, the dipole layer includes one or more selected from the group consisting of aluminum oxide, calcium oxide, gallium oxide, lutetium oxide, magnesium oxide, scandium oxide, yttrium oxide, and zinc oxide. In an embodiment, the channel region includes Si or SiGe.

Another embodiment of the disclosure is a method of manufacturing a semiconductor device including forming a plurality of spaced-apart nanostructures arranged along a first direction over a substrate and forming an interfacial layer around each of the plurality of nanostructures. A metal-containing layer is formed around the interfacial layers. The interfacial layer and the metal-containing layer are annealed to form a metal silicate layer around the nanostructures. A portion of the metal silicate layer is removed. A gate dielectric layer is formed around the nanostructures after removing a portion of the metal silicate layer, a gate electrode layer is formed around the gate dielectric layers. In an embodiment, the metal-containing layer includes a metal oxide or a metal nitride. In an embodiment, the metal-containing layer includes one or more metals selected from the group consisting of Al, Ga, Gd, Hf, La, Lu, Nd, Pr, Ta, Ti, Tm, Y, and Zr. In an embodiment, the gate dielectric layer includes one or more selected from the group consisting of hafnium oxide, zirconium oxide, aluminum oxide, hafnium zirconium oxide, yttrium oxide, and yttrium silicon oxide. In an embodiment, the method includes forming a dipole layer over the gate dielectric before forming the gate electrode layer. In an embodiment, the nanostructures comprise Si or SiGe.

Another embodiment of the disclosure is a method of manufacturing a semiconductor device including forming a first multilayer stack and a second multilayer stack over a substrate. The first and second multilayer stacks are spaced apart from each other along a first direction. An insulating layer is disposed between the spaced apart first and second multilayer stacks, and the first and second multilayer stacks include a plurality of spaced apart nanosheets arranged along a second direction perpendicular to the first direction. An oxide layer is formed surrounding each of the nanosheets. A metal-containing layer is formed surrounding each of the oxide layers. A portion of the metal-containing layer and the oxide layer is converted to a metal silicate layer. A portion of the metal-containing layer is removed. A gate dielectric layer is formed surrounding each of the nanosheets after removing the portion of the metal-containing layer, and a gate electrode layer is formed surrounding each of the gate dielectric layers. In an embodiment, the method includes forming the metal-containing layer over the insulating layer. In an embodiment, the method includes forming a hard mask layer over the gate dielectric layer in the first multilayer stack before forming the gate electrode layer. In an embodiment, the method includes forming a dipole layer over the hard mask layer in the first multilayer stack and over the gate dielectric layer in the second multilayer stack before forming the gate electrode layer. In an embodiment, the metal-containing layer includes one or more metals selected from the group consisting of Al, Ga, Gd, Hf, La, Lu, Nd, Pr, Ta, Ti, Tm, Y, and Zr.

Another embodiment of the disclosure is a semiconductor device including an interfacial layer disposed over a channel region, and a metal-containing layer disposed over the interfacial layer. A gate dielectric layer is disposed over the metal-containing layer, and a gate electrode layer is disposed over the gate dielectric layer. In an embodiment, the metal-containing layer includes a metal silicate. In an embodiment, the metal-containing layer includes one or more metals selected from the group consisting of Al, Ga, Gd, Hf, La, Lu, Nd, Pr, Ta, Ti, Tm, Y, and Zr. In an embodiment, a concentration of a metal in the metal-containing layer ranges from 25 ppm to 2 at. %. In an embodiment, the concentration of the metal in the metal-containing layer ranges from 50 ppm to 1 at. %. In an embodiment, a thickness of the metal-containing layer ranges from 0.1 nm to 1.5 nm. In an embodiment, the thickness of the metal-containing layer ranges from 0.2 nm to 0.7 nm. In an embodiment, the semiconductor device includes one or more work function adjustment layers disposed between the gate dielectric layer and the gate electrode layer. In an embodiment, a first work function adjustment layer comprises W, Co, Ni, Ti, TiN, TiSiN, WCN, TiWN, Ta, TaN, or WN. In an embodiment, a second work function adjustment layer is disposed over the first work function adjustment layer, and the second work function adjustment layer comprises TiAl, TiAlN, TiAlC, TiC, TaAlC, or TaC.

Another embodiment of the disclosure is a semiconductor device including a plurality of spaced-apart nanostructures arranged along a first direction over a substrate. An interfacial layer surrounds each of the nanostructures. A metal-containing layer surrounds each of the interfacial layers. A gate dielectric layer surrounds each of the metal-containing layers, and a gate electrode layer surrounds each of the gate dielectric layers. In an embodiment, the metal-containing layer includes a metal silicate. In an embodiment, the metal-containing layer includes one or more metals selected from the group consisting of Al, Ga, Gd, Hf, La, Lu, Nd, Pr, Ta, Ti, Tm, Y, and Zr. In an embodiment, a concentration of a metal in the metal-containing layer ranges from 25 ppm to 2 at. %. In an embodiment, a thickness of the metal-containing layer ranges from 0.1 nm to 1.5 nm.

Another embodiment of the disclosure is a semiconductor device including a first multilayer stack and a second multilayer stack disposed over a substrate. The first and second multilayer stacks are spaced apart from each other along a first direction, and an insulating layer disposed between the spaced apart first and second multilayer stacks. The first and second multilayer stacks include a plurality of spaced apart nanosheets arranged along a second direction perpendicular to the first direction. An oxide layer surrounds each of the nanosheets. A metal-containing layer surrounds each of the oxide layers. A gate dielectric layer surrounds each of the metal-containing layers, and a gate electrode layer surrounds each of the gate dielectric layers. In an embodiment, the nanosheets include Si or SiGe. In an embodiment, the metal-containing layer is disposed over the insulating layer. In an embodiment, the metal-containing layer includes one or more metals selected from the group consisting of Al, Ga, Gd, Hf, La, Lu, Nd, Pr, Ta, Ti, Tm, Y, and Zr. In an embodiment, a concentration of the metals in the metal-containing layer ranges from 25 ppm to 2 at. %. In an embodiment, the semiconductor device includes a first work function adjustment layer disposed between the gate dielectric layers and the gate electrode layers of the first and second multilayer stacks, and a second work function adjustment layer disposed over the first work function adjustment layer of the first multilayer stack, wherein the first work function adjustment layer, the second work function adjustment layer, and the gate electrode layer are made of different materials.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of spaced-apart nanostructures arranged along a first direction over a substrate;
an interfacial layer surrounding each of the nanostructures;
a metal-containing layer surrounding each of the interfacial layers;
a gate dielectric layer surrounding each of the metal-containing layers; and
a gate electrode layer surrounding each of the gate dielectric layers.

2. The semiconductor device of claim 1, wherein the metal-containing layer includes a metal silicate.

3. The semiconductor device of claim 1, wherein the metal-containing layer includes one or more metals selected from the group consisting of Al, Ga, Gd, Hf, La, Lu, Nd, Pr, Ta, Ti, Tm, Y, and Zr.

4. The semiconductor device of claim 1, wherein a concentration of a metal in the metal-containing layer ranges from 25 ppm to 2 at. %.

5. The semiconductor device of claim 1, wherein a thickness of the metal-containing layer ranges from 0.1 nm to 1.5 nm.

6. The semiconductor device of claim 1, wherein a thickness of the metal-containing layer ranges from 0.2 nm to 0.7 nm.

7. A semiconductor device, comprising:
a first multilayer stack and a second multilayer stack disposed over a substrate,
wherein the first and second multilayer stacks are spaced apart from each other along a first direction,
an insulating layer disposed between the spaced apart first and second multilayer stacks, and
the first and second multilayer stacks include a plurality of spaced apart nanosheets arranged along a second direction perpendicular to the first direction;
an oxide layer surrounding each of the nanosheets;
a metal-containing layer surrounding each of the oxide layers;
a gate dielectric layer surrounding each of the metal-containing layers; and
a gate electrode layer surrounding each of the gate dielectric layers.

8. The semiconductor device of claim 7, wherein the nanosheets comprise Si or SiGe.

9. The semiconductor device of claim 7, wherein the metal-containing layer is disposed over the insulating layer.

10. The semiconductor device of claim 7, wherein a thickness of the metal-containing layer ranges from 0.2 nm to 0.7 nm.

11. The semiconductor device of claim 7, wherein the metal-containing layer includes one or more metals selected from the group consisting of Al, Ga, Gd, Hf, La, Lu, Nd, Pr, Ta, Ti, Tm, Y, and Zr.

12. The semiconductor device of claim 11, wherein a concentration of the metals in the metal-containing layer ranges from 25 ppm to 2 at. %.

13. The semiconductor device of claim 11, further comprising:
a first work function adjustment layer disposed between the gate dielectric layers and the gate electrode layers of the first and second multilayer stacks; and
a second work function adjustment layer disposed over the first work function adjustment layer of the first multilayer stack,
wherein the first work function adjustment layer, the second work function adjustment layer, and the gate electrode layer are made of different materials.

14. The semiconductor device of claim 13, wherein a first work function adjustment layer comprises W, Co, Ni, Ti, TiN, TiSiN, WCN, TiWN, Ta, TaN, or WN.

15. The semiconductor device of claim 14, wherein a second work function adjustment layer is disposed over the first work function adjustment layer, and the second work function adjustment layer comprises TiAl, TiAlN, TiAlC, TiC, TaAlC, or TaC.

16. A method of manufacturing a semiconductor device, comprising:
forming a first multilayer stack and a second multilayer stack over a substrate,
wherein the first and second multilayer stacks are spaced apart from each other along a first direction,
an insulating layer is disposed between the spaced apart first and second multilayer stacks, and
the first and second multilayer stacks include a plurality of spaced apart nanosheets arranged along a second direction perpendicular to the first direction;
forming an oxide layer surrounding each of the nanosheets;
forming a metal-containing layer surrounding each of the oxide layers;
converting a portion of the metal-containing layer and the oxide layer to a metal silicate layer;
removing a portion of the metal-containing layer;
forming a gate dielectric layer surrounding each of the nanosheets after removing the portion of the metal-containing layer; and
forming a gate electrode layer surrounding each of the gate dielectric layers.

17. The method according to claim 16, further comprising forming the metal-containing layer over the insulating layer.

18. The method according to claim 16, further comprising forming a hard mask layer over the gate dielectric layer in the first multilayer stack before forming the gate electrode layer.

19. The method according to claim 18, further comprising forming a dipole layer over the hard mask layer in the first multilayer stack and over the gate dielectric layer in the second multilayer stack before forming the gate electrode layer.

20. The method according to claim 16, wherein the metal-containing layer includes one or more metals selected from the group consisting of Al, Ga, Gd, Hf, La, Lu, Nd, Pr, Ta, Ti, Tm, Y, and Zr.
